(19) United States
(12) Patent Application Publication
(10) Pub. No.: US 2025/0244431 A1
(43) Pub. Date: Jul. 31, 2025

(54) METHODS, DEVICES, AND SYSTEMS TO PERFORM MAGNETIC RESONANCE IMAGING

(71) Applicant: The Board of Trustees of the University of Illinois, Urbana, IL (US)

(72) Inventor: Kwan-Jin Jung, Champaign, IL (US)

(21) Appl. No.: 19/041,101

(22) Filed: Jan. 30, 2025

Related U.S. Application Data
(60) Provisional application No. 63/627,573, filed on Jan. 31, 2024.
(60) Provisional application No. 63/568,473, filed on Mar. 22, 2024.

(51) Int. Cl. G01R 33/563; G01R 33/48; G01R 33/56

(52) U.S. Cl. CPC G01R 33/56341; G01R 33/4816; G01R 33/4818; G01R 33/5608

(57) ABSTRACT

Methods, apparatus, and storage medium for enhancing diffusion-weighted magnetic resonance imaging (MRI) by using steady-state free procession (SSFP) of ultra-short echo time (UTE) and UTE-based magnetization transfer MRI. One method includes, for each of a plurality of data acquisition sequences: for each of a plurality of data acquisition sequences: applying a set of radio-frequency (RF) pulses to interact with transverse magnetization within an imaging volume of an object in a magnetic field, applying a three-dimension (3D) magnetic gradient within the imaging volume, wherein the 3D magnetic gradient comprises a 3D spiral pulse, and acquiring, during the 3D spiral pulse, raw imaging data from the imaging volume; and constructing a raw MRI image based on the raw imaging data acquired from the plurality of data acquisition sequences.

### PRIORITY AND RELATED APPLICATION

This application claims priority to U.S. Provisional Application No. 63/627,573, filed Jan. 31, 2024, which is incorporated by reference in its entirety. This application also claims priority to U.S. Provisional Application No. 63/568,473, filed Mar. 22, 2024, which is incorporated by reference in its entirety.

### TECHNICAL FIELD

This disclosure relates to magnetic resonance imaging (MRI), particularly to the enhancement of diffusion-weighted MRI using steady-state free procession (SSFP) of ultra-short echo time (UTE) and UTE-based magnetization transfer MRI.

### BACKGROUND

Magnetic resonance imaging (MRI) is a widely deployed medical imaging in biomedical research and in clinics. In some applications, higher magnetic field is desirable in order to obtain images with details with sharper and better contrast. However, the high magnetic field associates with a number of issues/problems related to image distortions. For one example, a geometric distortion may occur due to magnetic field inhomogeneity, and becomes worse at a higher magnetic field strength such as 7 Tesla. For another example, non-uniform image sensitivity over the image field-of-view may occur due to radio-frequency (RF) transmission inhomogeneity, which becomes more serious at a higher magnetic field strength such as 7 Tesla. For another example, at a higher magnetic field strength such as 7 Tesla, higher-frequency pulses may not penetrate as far into tissue, thus limiting imaging depth. For another example, at a higher magnetic field strength such as 7 Tesla, conventional diffusion imaging sequence may fail in producing a spatially uniform diffusion weighting due to severe inhomogeneity of RF transmission of the refocusing 180-degree RF pulses.

The present disclosure describes various embodiments for enhancing MRI using steady-state free procession (SSFP) of ultra-short echo time (UTE) and UTE-based magnetization transfer MRI, addressing at least one of the issues/problems discussed above, enhancing MRI image quantity and improving the technical field of MRI.

### SUMMARY

The present disclosure relates to methods, devices, and systems for enhancement of diffusion-weighted (DW) magnetic resonance imaging (MRI) using steady-state free procession (SSFP) of ultra-short echo time (UTE) and enhancement of UTE-based magnetization transfer MRI.

The present disclosure describes a method for performing magnetic resonance imaging (MRI) by a device comprising a memory storing instructions and a processor in communication with the memory. The method may include a portion or all of the following steps: for each of a plurality of data acquisition sequences: applying a set of radio-frequency (RF) pulses to interact with transverse magnetization within an imaging volume of an object in a magnetic field, applying a three-dimension (3D) magnetic gradient within the imaging volume, wherein the 3D magnetic gradient comprises a 3D spiral pulse, and acquiring, during the 3D spiral pulse, raw imaging data from the imaging volume; and constructing a raw MRI image based on the raw imaging data acquired from the plurality of data acquisition sequences.

The present disclosure describes a non-transitory computer readable storage medium storing computer readable instructions. The computer readable instructions, when executed by a processor, are configured to cause the processor to perform any portion/all of any of the methods described in the present disclosure; or to perform any combination of portions/all of more than one of the methods described in the present disclosure.

The present disclosure also describes an apparatus including electric circuitry configured to implement any of the above methods.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The system, device, product, and/or method described below may be better understood with reference to the following drawings and description of non-limiting and non-exhaustive embodiments. The components in the drawings are not necessarily to scale. Emphasis instead is placed upon illustrating the principles of the present disclosure.

FIG. 1 shows an example device for performing one or more embodiment in the present disclosure.

FIG. 2 shows a computer system that may be used to implement various components in an apparatus/device or various steps in a method described in the present disclosure.

FIG. 3A shows a flow diagram of an embodiment of various methods in the present disclosure.

FIG. 3B shows a flow diagram of another embodiment of various methods in the present disclosure.

FIG. 4A shows an exemplary sequence of a method described in the present disclosure.

FIG. 4B shows a schematic view of a three-dimension k-space.

FIG. 4C shows another exemplary sequence of various methods described in the present disclosure.

FIG. 4D shows another exemplary sequence of various methods described in the present disclosure.

FIG. 5 shows another exemplary sequence and related k-space of various methods described in the present disclosure.

FIG. 6 shows some exemplary results of various embodiments described in the present disclosure.

FIG. 7 shows some exemplary results of various embodiments described in the present disclosure.

FIG. 8 shows some exemplary results of various embodiments described in the present disclosure.

FIG. 9 shows another exemplary sequence and related k-space of various methods described in the present disclosure.

FIG. 10 shows some exemplary results of various embodiments described in the present disclosure.

FIG. 11 shows some exemplary results of various embodiments described in the present disclosure.

FIG. 12 shows some exemplary results of various embodiments described in the present disclosure.

FIG. 13 shows some exemplary results of various embodiments described in the present disclosure.

FIG. 14 shows some exemplary results of various embodiments described in the present disclosure.

FIG. 15 shows some exemplary results of various embodiments described in the present disclosure.

FIG. 16 shows some exemplary sequences of another embodiment described in the present disclosure.

FIG. 17 shows some exemplary results of various embodiments described in the present disclosure.

FIG. 18A shows some exemplary sequences of various embodiment described in the present disclosure.

FIG. 18B shows some exemplary sequences of various embodiment described in the present disclosure.

FIG. 19 shows some schematic diagrams of various embodiment described in the present disclosure.

FIG. 20 shows some exemplary sequences of various embodiment described in the present disclosure.

FIG. 21 shows an exemplary graphic user interface of various embodiment described in the present disclosure.

FIG. 22 shows another exemplary graphic user interface of various embodiment described in the present disclosure.

FIG. 23 shows some exemplary sequences of various embodiment described in the present disclosure.

FIG. 24 shows some exemplary sequences of various embodiment described in the present disclosure.

FIG. 25 shows some exemplary sequences of various embodiment described in the present disclosure.

FIG. 26 shows some exemplary sequences of various embodiment described in the present disclosure.

FIG. 27 shows some exemplary sequences of various embodiment described in the present disclosure.

FIG. 28 shows some exemplary sequences of various embodiment described in the present disclosure.

FIG. 29 shows some exemplary sequences of various embodiment described in the present disclosure.

FIG. 30 shows some exemplary sequences of various embodiment described in the present disclosure.

FIG. 31 shows some exemplary sequences of various embodiment described in the present disclosure.

FIG. 32 shows some exemplary results of various embodiments described in the present disclosure.

FIG. 33 shows some exemplary results of various embodiments described in the present disclosure.

FIG. 34 shows some exemplary results of various embodiments described in the present disclosure.

FIG. 35 shows some exemplary results of various embodiments described in the present disclosure.

FIG. 36 shows some exemplary results of various embodiments described in the present disclosure.

FIG. 37 shows some exemplary results of various embodiments described in the present disclosure.

FIG. 38 shows some exemplary results of various embodiments described in the present disclosure.

FIG. 39 shows some exemplary results of various embodiments described in the present disclosure.

FIG. 40 shows some exemplary results of various embodiments described in the present disclosure.

FIG. 41 shows some exemplary results of various embodiments described in the present disclosure.

### DETAILED DESCRIPTION

The disclosed systems, devices, and methods will now be described in detail hereinafter with reference to the accompanied drawings that form a part of the present application and show, by way of illustration, examples of specific embodiments. The described systems and methods may, however, be embodied in a variety of different forms and, therefore, the claimed subject matter covered by this disclosure is intended to be construed as not being limited to any of the embodiments. This disclosure may be embodied as methods, devices, components, or systems. Accordingly, embodiments of the disclosed system and methods may, for example, take the form of hardware, software, firmware or any combination thereof.

Throughout the specification and claims, terms may have nuanced meanings suggested or implied in context beyond an explicitly stated meaning. Likewise, the phrase “in one embodiment” or “in some embodiments” as used herein does not necessarily refer to the same embodiment and the phrase “in another embodiment” or “in other embodiments” as used herein does not necessarily refer to a different embodiment. It is intended, for example, that claimed subject matter may include combinations of exemplary embodiments in whole or in part. Moreover, the phrase “in one implementation”, “in another implementation”, “in some implementations”, or “in some other implementations” as used herein does not necessarily refer to the same implementation(s) or different implementation(s). It is intended, for example, that claimed subject matter may include combinations of the disclosed features from the implementations in whole or in part.

In general, terminology may be understood at least in part from usage in context. For example, terms, such as “and”, “or”, or “and/or,” as used herein may include a variety of meanings that may depend at least in part upon the context in which such terms are used. In addition, the term “one or more” or “at least one” as used herein, depending at least in part upon context, may be used to describe any feature, structure, or characteristic in a singular sense or may be used to describe combinations of features, structures or characteristics in a plural sense. Similarly, terms, such as “a”, “an”, or “the”, again, may be understood to convey a singular usage or to convey a plural usage, depending at least in part upon context. In addition, the term “based on” or “determined by” may be understood as not necessarily intended to convey an exclusive set of factors and may, instead, allow for existence of additional factors not necessarily expressly described, again, depending at least in part on context.

The present disclosure describes various embodiments for enhancement of diffusion-weighted (DW) magnetic resonance imaging (MRI) using steady-state free procession (SSFP) of ultra-short echo time (UTE) and UTE-based magnetization transfer MRI.

In some implementations, a conventional sequence (e.g., a spin echo sequence) may be used for faster scanning and reduction of motion artifacts. However, this method may have some issues/problems, for example, geometric distortion due to magnetic field inhomogeneity and/or non-uniform image sensitivity over the image field of-view due to RF transmission inhomogeneity. In some applications, higher magnetic field is desirable for obtaining images with details with sharper and better contrast. However, the high magnetic field associates with a number of issues/problems related to image distortions. For one example, a geometric distortion may occur due to magnetic field inhomogeneity, and becomes worse at a higher magnetic field strength such as 7 Tesla. For another example, non-uniform image sensitivity over the image field-of-view may occur due to RF transmission inhomogeneity, which becomes more serious at a higher magnetic field strength such as 7 Tesla. For another example, at a higher magnetic field strength such as 7 Tesla, higher-frequency pulses may not penetrate as far into tissue, thus limiting imaging depth. For another example, at a higher magnetic field strength such as 7 Tesla, conventional diffusion imaging sequence may fail in producing a spatially uniform diffusion weighting due to severe inhomogeneity of RF transmission of the refocusing 180-degree RF pulses.

The present disclosure describes various embodiments for enhancing MRI using steady-state free procession (SSFP) of ultra-short echo time, addressing at least one of the issues/problems discussed above, enhancing MRI image quantity and improving the technical field of MRI at a higher magnetic field strength such as 7 Tesla. Some methods may resolve or reduce a portion or all of the above discussed problems with improved features. In addition to these advantages, the new sequence has additional improved features such as an ultra-short echo time to reduce the signal reduction due to a local susceptibility, three-dimensional excitation and acquisition for a better signal-to-noise ratio, and/or a non-Cartesian (or non-rectangular), i.e., spiral, readout trajectory for an ultra-short echo time and a faster scan time.

Various embodiments may overcome some issues/problems (e.g., image distortions and/or non-uniform image sensitivity) by using a portion or all of the following improvements: diffusion imaging using SSFP instead of traditional spin echo configuration, spiral trajectories instead of echo planar Imaging (EPI), and/or 30-degree RF pulses instead of 180-degree RF pulses. In some implementations, a method may combine diffusion weighted (DW) SSFP with spiral trajectory using 30-degree water-selective RF pulses.

Various embodiments in the present disclosure may provide a portion or all of the following advantages over some other methods: less geometric distortion (e.g., at 3 Tesla, or 7 Tesla), uniform image sensitivity, ultra short echo times (reduces signal reduction due to local susceptibility and small T2* relaxation time), more suitable and/or useable for imaging muscle fibers, three-dimension (3D) excitation and acquisition (reduces signal to noise ratio), faster scan time because of spiral trajectories; not requiring image-correcting algorithms; and/or spiral trajectories being less sensitive to patient motion than planar imaging.

The enhanced imaging quality and/or high level of detail may allow researchers in biomedical research and development and/or clinicians in clinics/hospitals to make observations, diagnostics, and/or treatment that would not otherwise be possible, for a non-limiting example, being used to definitively identify and diagnose early signs of focal cortical dysplasia, or epilepsy.

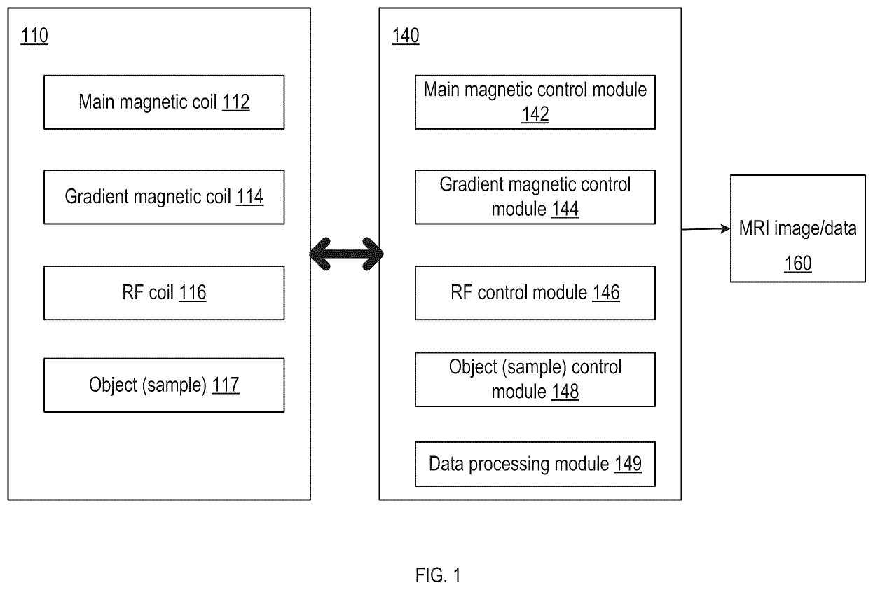

Various embodiments in the present disclosure may be partially or totally performed using a MRI device as shown in FIG. 1. The MRI device may include a magnetic assembly unit 110 and a system controller 140. In some implementations, the magnetic assembly unit 110 may include a portion or all of the following: one or more main magnetic coil 112, one or more gradient magnetic coil 114, one or more RF coil 116, and/or an object (or sample) and its supporting device 117. The system controller 140 may include a portion or all of the following: a main magnetic control module 142 (communicating with and/or powering one or more main magnetic coil); a gradient magnetic control module 144 (communicating with and/or powering one or more gradient magnetic coil); a RF control module 146 (communicating with and/or powering one or more RF coil); an object (sample) control module (communicating with and/or powering one or more object (sample)'s supporting device; and/or a data processing module 149. In some implementations, the data processing module may process raw data acquired from the magnetic assembly unit, and/or process image data (e.g., for output or display MRI image/data 160).

Magnetic resonance imaging (MRI) is based on sensing the magnetization properties of atomic nuclei in an object (sample). Normally, proton magnetization within water of the object (sample) is randomly oriented. When a strong external magnetic field is applied, the proton magnetization may be aligned. This alignment (or magnetization) may be perturbed/excited by one or more RF pulse. When the perturbation of the magnetization relaxes, the nuclei may return to un-perturbed (or resting) alignment, during which the nuclei may emit a radio frequency energy. The emitted radio frequency energy, which may be referred as echo signal, may be detected and measured for generating MRI images of the object (sample).

Repetition time (TR) may refer to the amount of time duration between successive RF pulse sequences applied to a slice of the sample. Echo time (TE) may refer to the amount of time duration between the RF pulse and the echo signal.

Signal processing (e.g., Fourier transformation) may be used to construct the MRI image. In some implementations, Fourier transformation may convert frequency information contained in the echo signal for locations in image plan to intensity level of certain pixels. At least two different relaxation time may be used to characterize the signal: T1 refers to a longitudinal relaxation time, and T2 refers to a transverse relaxation time. In some implementations, T1 is determined by a rate at which the excited nuclei (e.g., proton) return to resting state (i.e., equilibrium), and corresponds to the time duration for protons to realign with the strong external magnetic field. In some implementations, T2 is determined by a rate at which excited protons go out of phase with each other, and corresponds to the time duration for protons to lose phase coherence.

MRI images may include T1-weighted MRI image, T2-weighted MRI image, fluid attenuated inversion recovery (FLAIR) MRI image, diffusion-weighted MRI image (DW-MRI or DWI). DW-MRI measures diffusion of protons in water, which corresponds their random movement. The diffusion of protons in water (e.g., freely or restricted along one or more diffusion directions) can be detected to form DW-MRI image. Diffusion may be unidirectional (anisotropic) or uniform (isotropic). Combining images obtained with different amounts of diffusion weighting may generate a highly sensitive image (e.g., an apparent diffusion coefficient (ADC) image). Such DW-MRI images can be used to study or diagnose many types of object/sample (e.g., brain, liver, breast, etc.).

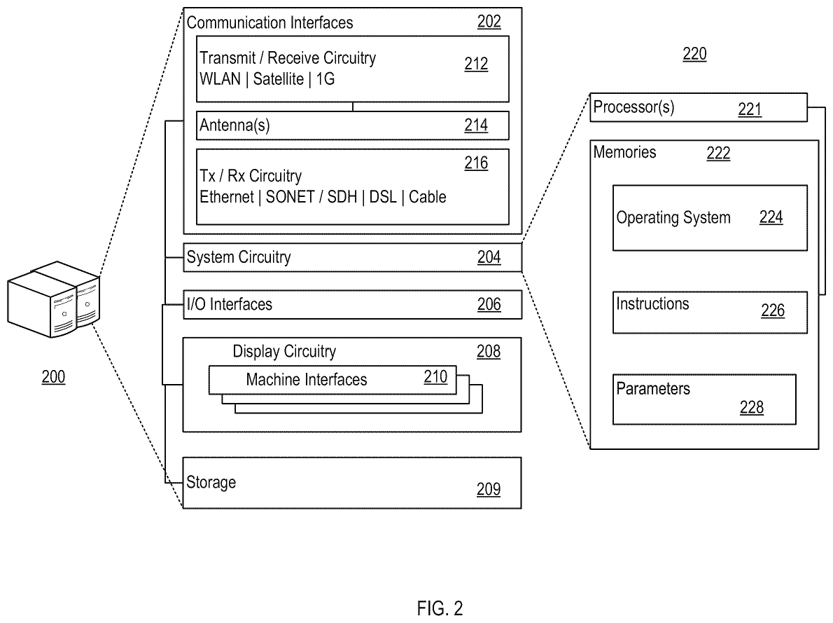

FIG. 2 shows an exemplary electronic device/apparatus, wherein any device, unit, or module in the present disclosure may include a portion or all of the components in the exemplary electronic device/apparatus. The electronic device/apparatus may include a computer system 200 for implementing one or more steps in various embodiments of the present disclosure. The computer system 200 may include communication interfaces 202, system circuitry 204, input/output (I/O) interfaces 206, storage 209, and display circuitry 208 that generates machine interfaces 210 locally or for remote display, e.g., in a web browser running on a local or remote machine. For one example, the computer system 200 may communicate with one or more instrument (e.g., a RF coil).

The machine interfaces 210 and the I/O interfaces 206 may include GUIs, touch sensitive displays, voice or facial recognition inputs, buttons, switches, speakers and other user interface elements. Additional examples of the I/O interfaces 206 include microphones, video and still image cameras, headset and microphone input/output jacks, Universal Serial Bus (USB) connectors, general purpose digital interface (GPIB), peripheral component interconnect (PCI), PCI extensions for instrumentation (PXI), memory card slots, and other types of inputs. The I/O interfaces 206 may further include magnetic or optical media interfaces (e.g., a CDROM or DVD drive), serial and parallel bus interfaces, and keyboard and mouse interfaces.

The communication interfaces 202 may include wireless transmitters and receivers (“transceivers”) 212 and any antennas 214 used by the transmitting and receiving circuitry of the transceivers 212. The transceivers 212 and antennas 214 may support Wi-Fi network communications, for instance, under any version of IEEE 802.11, e.g., 802.11n or 802.11ac. The communication interfaces 202 may also include wireline transceivers 216. The wireline transceivers 216 may provide physical layer interfaces for any of a wide range of communication protocols, such as any type of Ethernet, data over cable service interface specification (DOCSIS), digital subscriber line (DSL), Synchronous Optical Network (SONET), or other protocol.

The storage 209 may be used to store various initial, intermediate, or final data or model for implementing the embodiment for determining at least one reaction condition. These data corpus may alternatively be stored in a database 118. In one implementation, the storage 209 of the computer system 200 may be integral with a database. The storage 209 may be centralized or distributed, and may be local or remote to the computer system 200. For example, the storage 209 may be hosted remotely by a cloud computing service provider.

The system circuitry 204 may include hardware, software, firmware, or other circuitry in any combination. The system circuitry 204 may be implemented, for example, with one or more systems on a chip (SoC), application specific integrated circuits (ASIC), microprocessors, discrete analog and digital circuits, and other circuitry.

For example, at least some of the system circuitry 204 may be implemented as processing circuitry 220. The processing circuitry 220 may include one or more processors 221 and memories 222. The memories 222 stores, for example, control instructions 226, parameters 228, and/or an operating system 224. The control instructions 226, for example may include instructions for implementing one or more steps of various embodiments. In one implementation, the instruction processors 221 execute the control instructions 226 and the operating system 224 to carry out any desired functionality related to the embodiment.

The present disclosure describes various embodiments of methods and/or apparatus for enhancing DW-MRI using SSFP of ultra-short echo time, which may include or be implemented, either partially or totally, by an electric device/system as shown in FIG. 2.

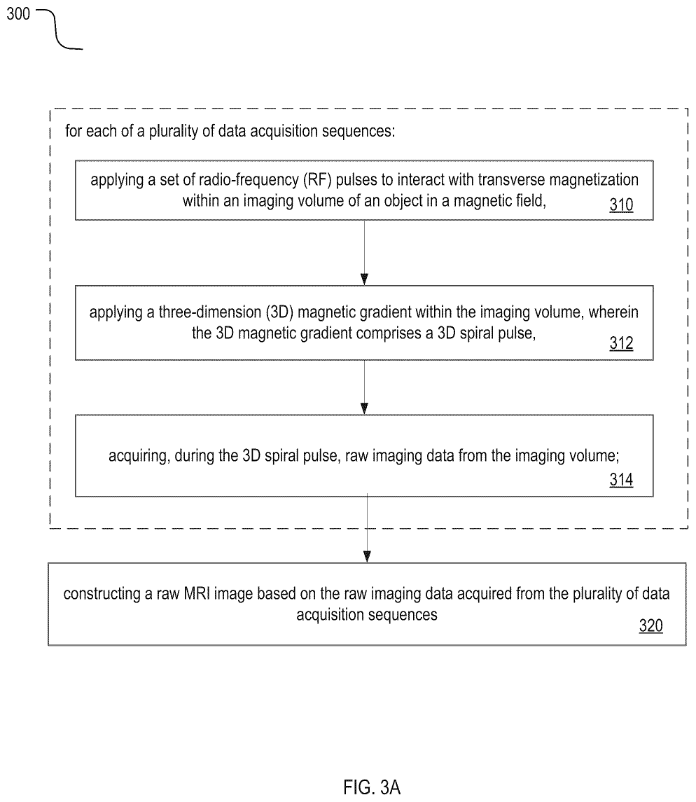

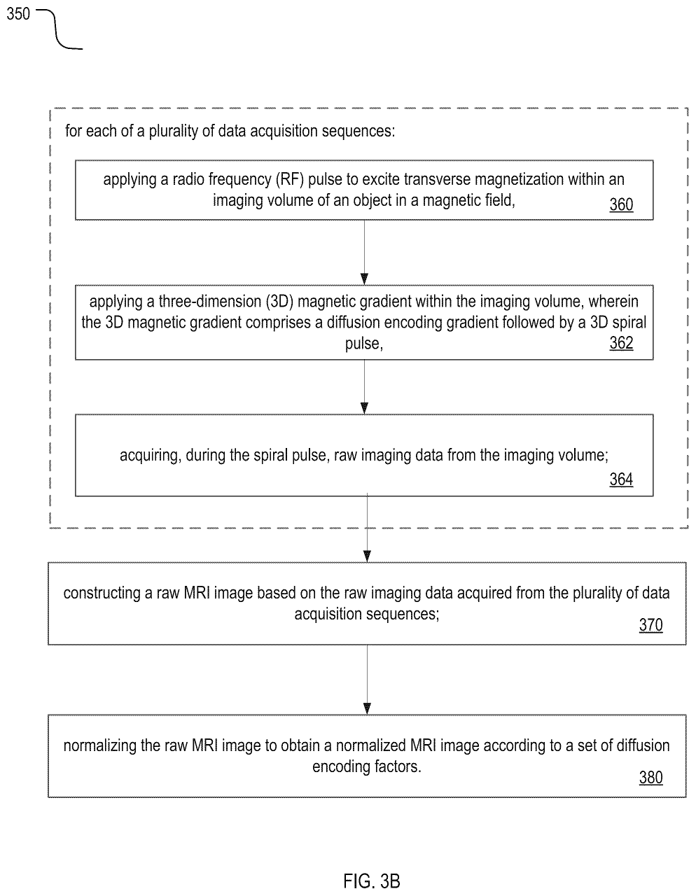

Referring to FIG. 3B, the present disclosure describes various embodiments of a method 350 for performing magnetic resonance imaging (MRI) by a device comprising a memory storing instructions and a processor in communication with the memory. The method 350 may include a portion or all of the following steps: for each of a plurality of data acquisition sequences: step 360, applying a radio-frequency (RF) pulse to excite transverse magnetization within an imaging volume of an object in a magnetic field, step 362, applying a three-dimension (3D) magnetic gradient within the imaging volume, wherein the 3D magnetic gradient comprises a diffusion encoding gradient followed by a 3D spiral pulse, and/or step 364, acquiring, during the spiral pulse, raw imaging data from the imaging volume; step 370, constructing a raw MRI image based on the raw imaging data acquired from the plurality of data acquisition sequences; and/or step 380, normalizing the raw MRI image to obtain a normalized MRI image according to a set of diffusion encoding factors.

In various embodiments in the present disclosure, a “volume” may be used to represent a 3D object, and a “slice” may be used to represent a thin 2D slice of a 3D volume.

In some implementations, the diffusion encoding gradient comprises a diffusion-weighted (DW) steady-state free procession (SSFP) gradient.

In some implementations, the 3D spiral pulse comprises a time-variant magnetic gradient along at least two axes to form a spiral-in trajectory in a two-dimension (2D) disc in a 3D k-space. Here, a “k-space” refer to a spatial frequency domain corresponding to precession frequency related to RF pulse.

In some implementations, the time-variant magnetic gradient along at least two axes in the 3D changes from one data acquisition sequence to next data acquisition sequence to rotate the 2D disc to fill the 3D k-space.

In some implementations, the RF pulse is applied within at least one excitation resonance-frequency range to excite the transverse magnetization within the imaging volume.

In some implementations, the RF pulse corresponds to a 30-degree flip angle.

In some implementations, the RF pulse comprises a rectangular RF pulse.

In some implementations, the magnetic field is about 7 Tesla. In the present disclosure, “about A” may refer to a range between 95% A and 105% A, inclusive.

In some implementations, the set of diffusion encoding factors correspond to a set of diffusion encoding directions.

In some implementations, the set of diffusion encoding factors are obtained based on reference signal of a reference sample at the set of diffusion encoding directions.

In some implementations, the reference sample has an isotropic diffusion property, and is a region-of-interest (ROI) within the object or a sample outside the object.

In some implementations, the acquiring, during the spiral pulse, the raw imaging data from the imaging volume comprises: acquiring, during the spiral, echo signal corresponding to the RF pulse from the imaging volume; and/or processing the echo signal to obtain the raw imaging data.

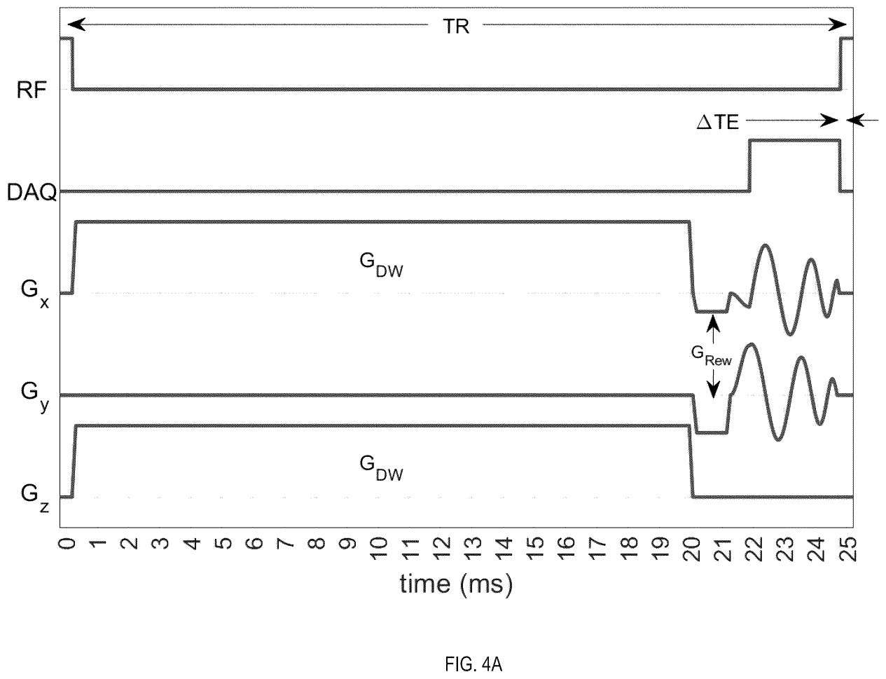

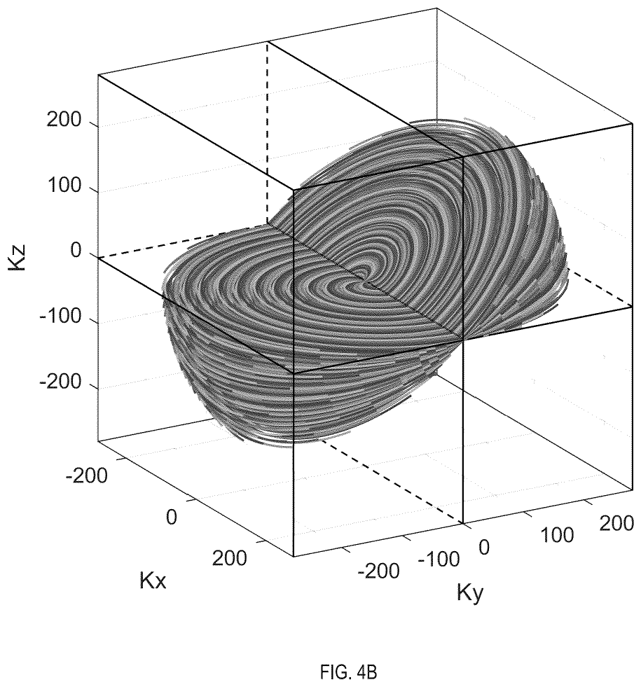

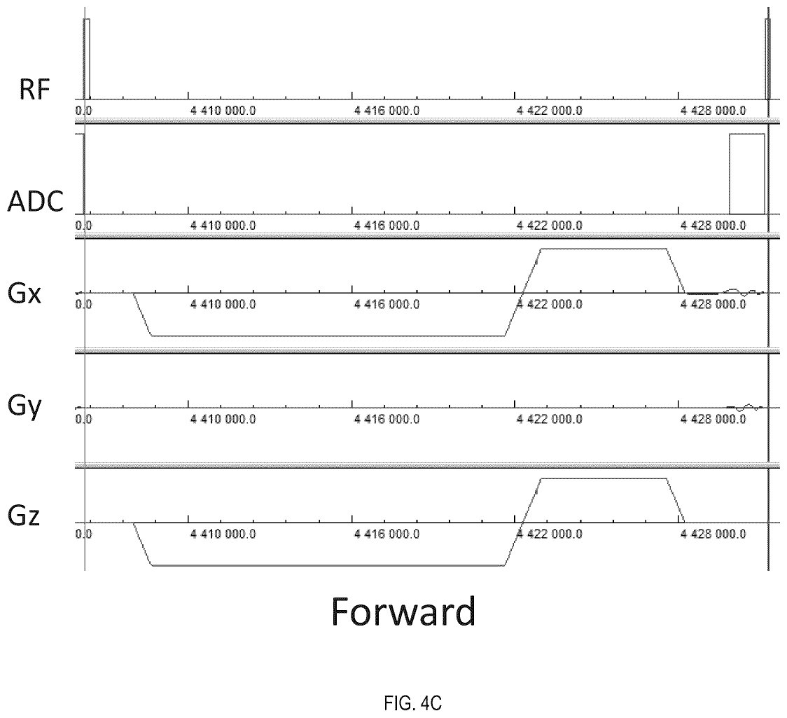

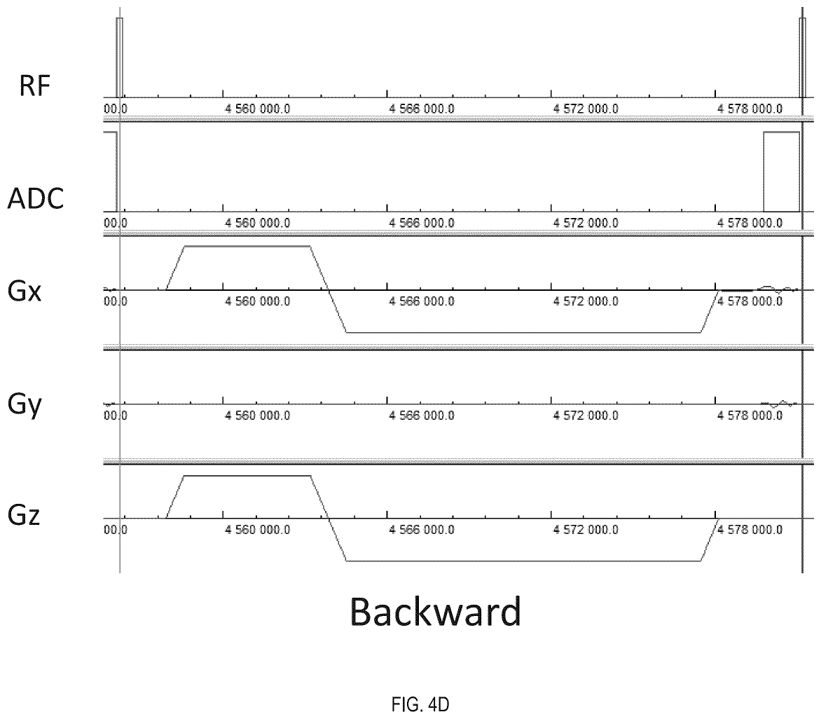

For a non-limiting example as shown in FIG. 4A, a RF pulse with a rectangular profile is applied on an object (sample) at 0 millisecond (ms) to begin a data acquisition sequence, and at a repetition time (TR), another RF pulse is applied for next data acquisition sequence.

Within a data acquisition sequence, after the RF pulse, a 3D magnetic gradient is applied along x, y, and z axes (corresponding to Gx, Gy, and Gz). The 3D magnetic gradient comprises a first portion (diffusion encoding gradient), and a second portion (3D spiral pulse). Raw signal (raw imaging data) is acquired during the second portion (3D spiral pulse) from the object (sample).

During the data acquisition sequence as shown in FIG. 4A, there is time-variant magnetic gradient for Gx and Gy in the second portion (3D spiral pulse), while there is zero magnetic gradient for Gz in the second portion (3D spiral pulse), forming a spiral-in trajectory in a 2D disc in the 3D k-space, as shown in FIG. 4B.

From one data acquisition sequence to next data acquisition sequence, the 3D spiral pulse may change its time-variant magnetic gradient along Gx, Gy, and/or Gz to rotate the 2D disc to fill the 3D k-space, as shown in FIG. 4B. For one non-limiting example from one data acquisition sequence to next data acquisition sequence, the time-variant magnetic gradient along Gx may decrease its amplitude while time-variant magnetic gradient along Gy may increase its amplitude. For another non-limiting example from one data acquisition sequence to next data acquisition sequence, the time-variant magnetic gradient along Gx and/or Gy may decrease its amplitude while time-variant magnetic gradient along Gz may increase its amplitude.

In some implementations, in order to perform velocity compensation, a forward and/or backward gradient profile may be applied to the first portion (diffusion encoding gradient) of the 3D magnetic gradient, as shown in FIGS. 4C and 4D. In some implementations, FIG. 4C and FIG. 4D are variations of FIG. 4A for velocity compensation.

The present disclosure describes various embodiments for enhancing DW-MRI using SSFP. The embodiments and/or example implementations below are intended to be illustrative embodiments and/or examples of the techniques and methods discussed above. The example implementations are not intended to constrain the above techniques and methods to particular features and/or examples but rather demonstrate real world implementations of the above techniques and methods. Further, the features discussed in conjunction with the various example implementations below may be individually (or in virtually any grouping) incorporated into various implementations of the techniques and methods discussed above with or without others of the features present in the various example implementations below.

### Embodiment Set I: UTE-Based DW-SSFP for Musculoskeletal MRI

The present disclosure describes various embodiments having a portion or all of the following features. For motivation, fiber tracking of ligaments suffers from a low signal due to their fast T2 relaxation during a long echo time in spin-echo EPI diffusion sequences. For goal(s), shorten the echo time of the diffusion sequence and acquire in 3D.

Various embodiments may use a 3D spiral-in readout in a DW-SSFP sequence to achieve that the 3D spiral-in readout features an enhanced signal, shorter TR or TE, a wider interval for diffusion gradients, reduced geometric distortion, and a minimized echo time shift. It is demonstrated for tracts of knee ligaments using ex vivo hind limbs of piglets.

Various embodiments may have impact that the diffusion imaging sequence provides a high sensitivity to musculoskeletal tissue with small T2 relaxation times. This will be useful in studying the muscles, tendons, ligaments, and cartilage.

In some implementations, T2 relaxation time of musculoskeletal tissues is known to be small. Hence, the spin-echo diffusion imaging sequence suffers from a low signal due to a long echo time in the spin-echo diffusion sequence with one or two refocusing 180° RF pulses. On the hand, DW-SSFP diffusion imaging sequence forms an echo without the refocusing RF pulse, hence it can be more sensitive to tissues with small T2 relaxation time. The DW-SSFP sequence can be further improved by employing the UTE sequence using a 3D spiral-in readout.

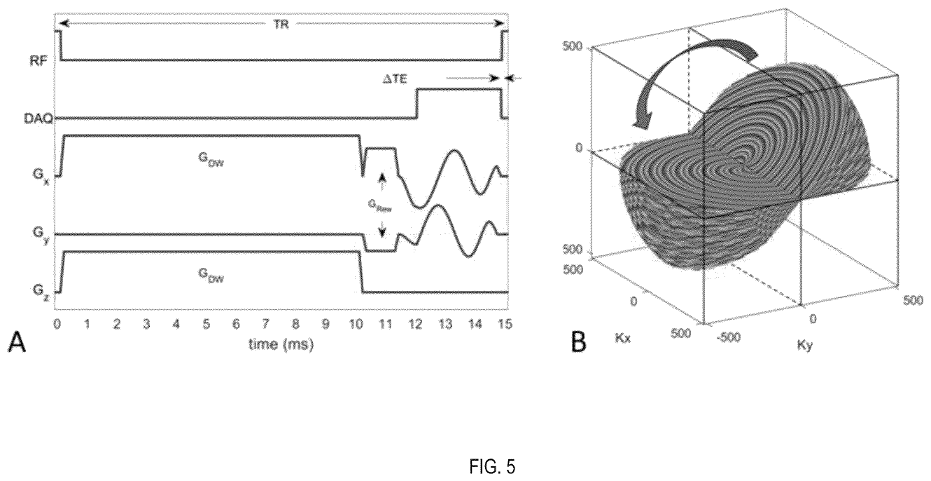

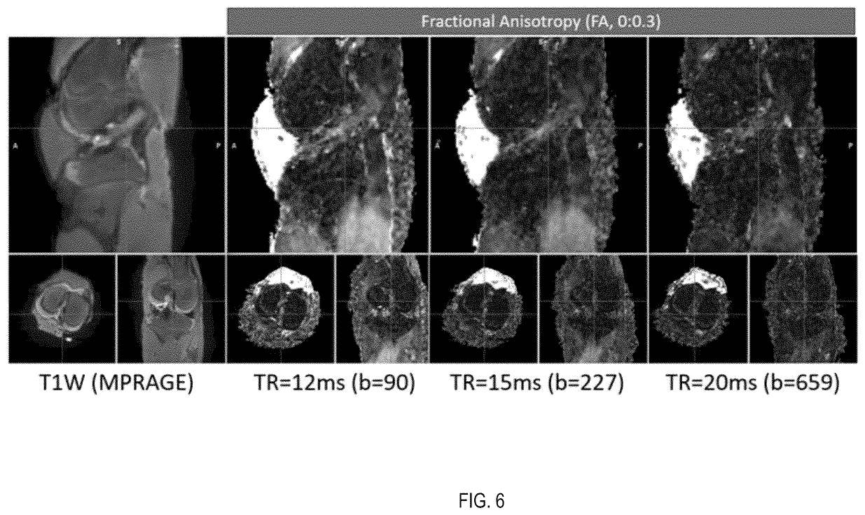

Various embodiments may include the following schemes. The DW-SSFP sequence with the 3D spiral trajectory is shown in FIG. 5. The echo shift (ΔTE) is minimized compared to the EPI readout, which can increase the duration of the diffusion encoding gradient (G_{DW}). One b0 volume was obtained with a small b value to spoil the FID component in SSFP, followed by 6 diffusion-weighted acquisitions with a large b value. The diffusion sensitivity or b value is dependent on TR and G_{DW}, hence the DW-SSFP sequence was run with 3 different TR's of 12, 15, and 20 ms. The scan parameters for TR=15 ms were: echo shift (ΔTE)=0.12 ms, voxel=1 mm isotropic, duration of G_{DW}=10.1 ms, amplitude of G_{DW}=37 mT/m, flip angle=30°, and scan time=14:58. The b values at the 3 TR's are listed in FIG. 6. At TR=15 ms, the b value for the b0 volume was 0.28 s/mm². The objects were ex vivo knee samples of 3 to 4 months old porcine. Four knee specimens were scanned using a 15-ch knee RF coil at 3T MRI. A T1W anatomy image was also obtained. The fractional anisotropy (FA) was estimated using DTIFIT of FSL. Fiber tracts of anterior and posterior cruciate ligaments (ACL and PCL) were traced and characterized using DSI Studio.

FIG. 5 shows DW-SSFP sequence diagrams. (A) One TR period of the sequence diagram is shown. It is a 3D sequence with a rectangular RF pulse. The readout is a spiral-in trajectory to minimize the echo shift (ΔTE). The rewind gradient (G_{Rew}) is to refocus the spiral readout in each TR. The diffusion encoding gradient (G_{DW}) is applied on x and z axes in this example diffusion encoding direction and they will be rotated for different diffusion encoding directions. (B) The spirals are interleaved to form a 2D K-space disc and the disc was rotated to fill the 3D K-space.

FIG. 6 shows comparison of FA maps acquired with different TR and b. The display window of FA maps was between FA=0 and 0.3. The b value was calculated for an echo from the immediately prior TR and its unit is s/mm². FA looked blurry at TR=12 ms and was in low signal at TR=20 ms. There was an anterior region with hyper-intensive FA, which was not artifacts.

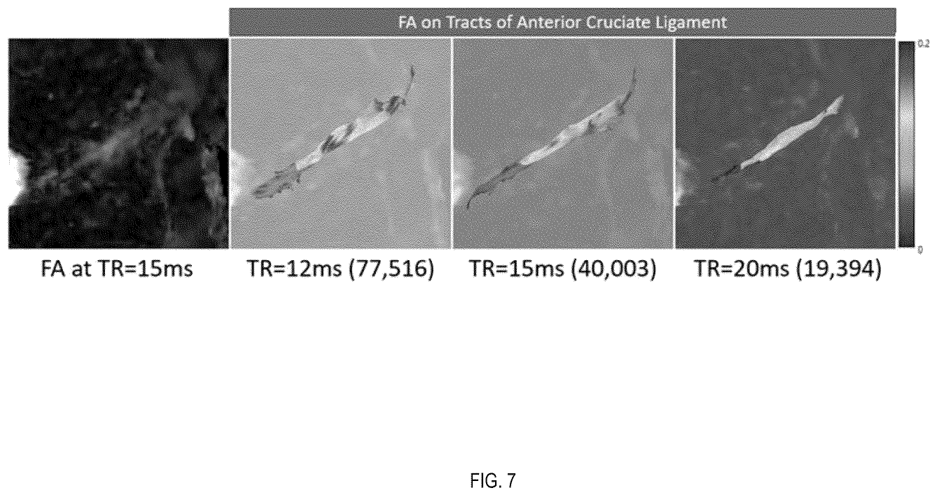

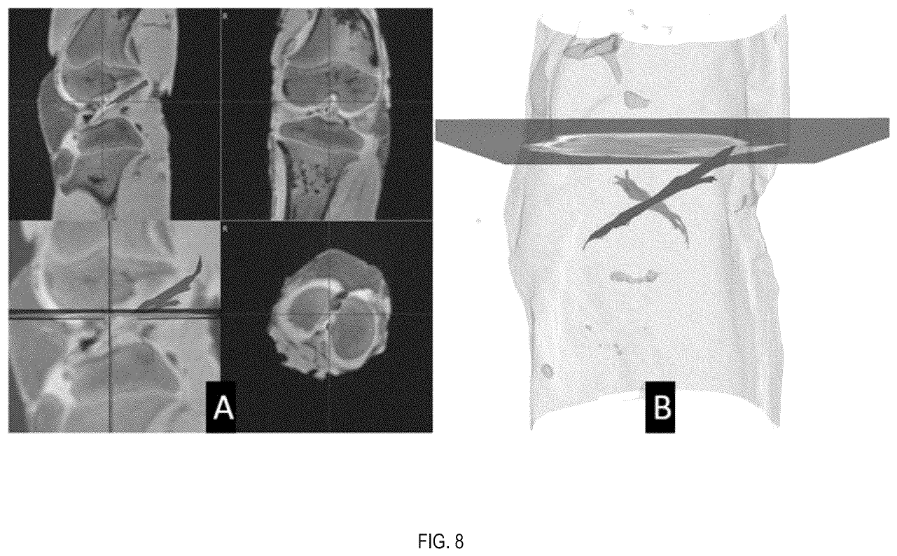

Various embodiments may have the following results. TR and b value had affected FA of ligaments (FIG. 6) and accordingly the tracts for the ACL tracts (FIG. 7). In these two figures, the FA map and tracts appeared more reasonable at TR=15 ms or b=226 s/mm². Tracts of ACL and PCL of one representative specimen at TR=15 ms are shown in FIG. 8 and their statistics are summarized in Table 1, which shows statistics of ACL and PCL tracts which are colored in red and green in FIG. 8, respectively. ACL was higher in FA and other measures than PCL.

FIG. 7 shows comparison of ACL tracts at different TR's. The left panel is the FA map at TR=15 ms. The tract colors represent FA. The number in the parenthesis is the number of tracts in each TR.

FIG. 8 shows ACL (red color) and PCL (green color) tracts overlaid on T1W image (A) and surface rendering of T1W image (B).

TABLE 1
Statistics of ACL and PCL tracts

| | ACL | PCL |
|---|---|---|
| Number of tracts | 40,003 | 8,420 |
| Mean length (mm) | 39 | 36 |
| Span (mm) | 76 | 68 |
| Diameter (mm) | 3.2 | 1.4 |
| Volume (mm³) | 306 | 57 |
| FA (fractional anisotropy) | 0.11 | 0.09 |
| MD (mean diffusivity) | 3.9 | 3.5 |
| AD (axial diffusivity) | 4.3 | 3.8 |
| RD (radial diffusivity) | 3.6 | 3.3 |

In some implementations, the echo time for diffusion in the DW-SSFP sequence with TR=15 ms was 30 ms for the echo pathway initiated from the immediately prior TR. This is smaller than the echo time achievable using the spin echo EPI. The spiral readout contributed to widening the diffusion encoding gradient. However, this made the duty cycle of the diffusion gradient greater than 75% at TR=15 ms, which limited the allowed maximum gradient amplitude from the scanner. The maximum gradient amplitude in the vendor specification is valid only for a small duty cycle. The spiral readout did not suffer from noticeable geometric distortion, which was a clear advantage over the EPI-based diffusion sequence in tracking the tracts. The 3D acquisition helped not only a higher signal, but also tracking a thin and tilted bundle of ACL and PCL tracts. Although the DW-SSFP is known to be extremely sensitive to motion, its in vivo application to knee is expected to be relatively manageable than the brain due to a low b value, no physiologic effect except at arteries, and the intrinsic robustness of spiral trajectory to flow and fluctuations.

In some implementations, the echo time of the proposed DW-SSFP sequence could be set within 30 ms with a diffusion encoding gradient sensitive enough for tracking knee ligaments in a whole-body MRI. Furthermore, this sequence did not suffer from geometric distortion and provided high signal for tracking knee ligaments.

### Embodiment Set II: UTE-Based DW-SSFP MRI for 7T

The present disclosure describes various embodiments having a portion or all of the following features. For motivation, at 7T the conventional spin-echo EPI diffusion sequence suffers from the B1+ inhomogeneity and geometric distortion due to refocusing RF pulses and EPI readout. For goal(s), to develop a diffusion imaging sequence without refocusing RF pulses and EPI readout at 7T.

Various embodiments may use a 3D DW-SSFP sequence with a spiral readout to reduce the geometric distortion, to maximize the diffusion gradient time, and to reduce susceptibility effect to achieve that the DW-SSFP sequence was successful in reducing the B1+ inhomogeneity, the geometric distortion, and the susceptibility effect compared to the spin-echo EPI diffusion sequence using cadaveric head specimens at 7T.

Various embodiments may have impact that the sequence enables the acquisition of high-resolution diffusion images that do not suffer from the B1+ inhomogeneity and geometric distortion often observed at 7T. It provides good quality fiber tracts and fractional anisotropy maps of the brain.

In some implementations, a spin-echo-based diffusion imaging sequence suffers from RF nonuniformity due to refocusing 180° RF pulses at 7T. In contrast, a diffusion-weighted steady state free precession (DW-SSFP) sequence uses a small flip angle RF pulse that reduces the RF nonuniformity in images at 7T. On the other hand, the EPI readout in diffusion imaging results in not only geometric distortions but also an increased echo shift from the echo center in DW-SSFP. These effects increase at 7T compared to 3T. Therefore, DW-SSFP sequence was used to reduce the RF nonuniformity and the spiral-based ultra-short-echo-time (UTE) readout was used to reduce the geometric distortion and the echo shift time. UTE-based DW-SSFP sequence on four cadaveric head specimens at 7T was demonstrated.

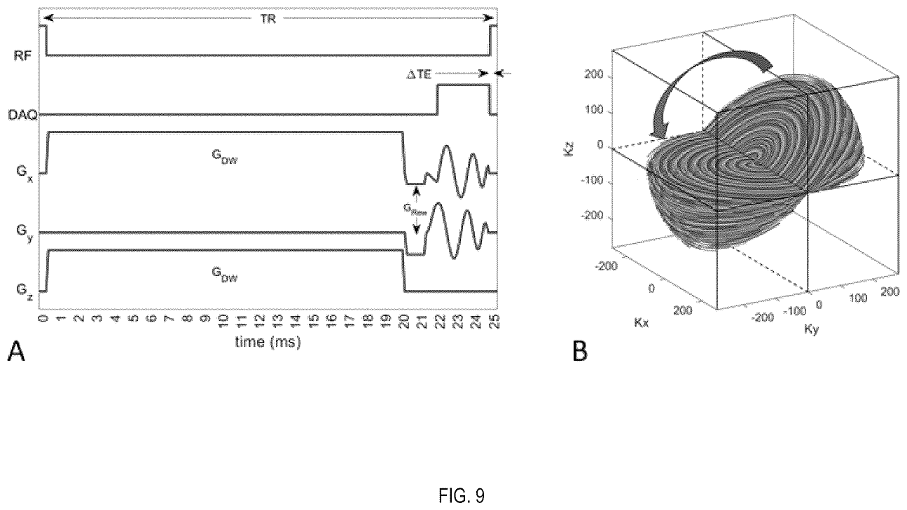

Various embodiments may include the following schemes. The DW-SSFP sequence with the 3D spiral trajectory is shown in FIG. 9. The echo shift (ΔTE) is minimized compared to the EPI readout, which allows a longer duration of the diffusion encoding gradient (G_{DW}). One volume of b0 was obtained with b=3.2 s/mm² to spoil the FID component in SSFP, followed by 6 diffusion-weighted acquisitions for 6 directions of MDDW with b=1420 s/mm². The b values were for the echo signal from the immediate prior TR. The scan parameters were: TR=25 ms, echo shift (ΔTE)=0.17 ms, voxel=2 mm isotropic, duration of G_{DW}=20 ms, amplitude of G_{DW}=37 mT/m, flip angle=30°, acceleration=2, and scan time=5:56. As a comparison, a multi-slice spin-echo EPI diffusion sequence with a bipolar diffusion gradient was used for DW-EPI with b=2000 s/mm² in 24 directions and 4 interleaved b0: TR/TE=6300/88 ms, voxel=2 mm isotropic, and scan time=3:47. Four cadaveric head specimens were acquired in a fresh and never-frozen state from an external lab (Science Care, Coral Spring, FL) and they were kept at 4° C. before MRI scans. The specimens had been flushed with cephalous-formalin. The four specimens were scanned at 7T: two with a single channel transmission (STX) head RF coil and the other two with an 8-ch parallel transmission (PTX) head RF coil. Additionally, anatomical images of 3-dimensional T1W (MP2RAGE) and T2W (SPACE) were collected. The MP2RAGE images were denoised using a lossless algorithm and normalized for the B1 sensitivity. The universal RF pulses were used for the T2W SPACE scan with the PTX coil. The fractional anisotropy (FA) was estimated using DTIFIT in FSL. The reduced geometric distortion of the DW-SSFP sequence was demonstrated by tracking the corticospinal tracts using DSI Studio.

FIG. 9 shows DW-SSFP sequence diagrams. (A) One TR period of the sequence diagram is shown. It is a 3D sequence with a rectangular RF pulse. The readout is a spiral-in trajectory to minimize the echo shift (ΔTE). The rewind gradient (G_{Rew}) is to refocus the spiral readout in each TR. The diffusion encoding gradient (G_{DW}) is applied on x and z axes in this example figure and they are rotated for different diffusion encoding directions. (B) The spiral leaves are interleaved to form a 2D K-space disc and the disc was rotated to fill the 3D K-space.

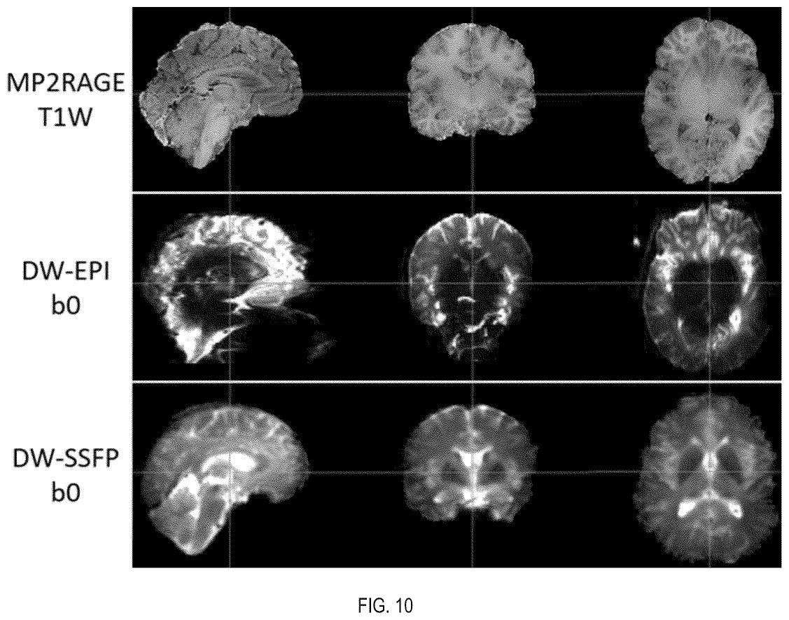

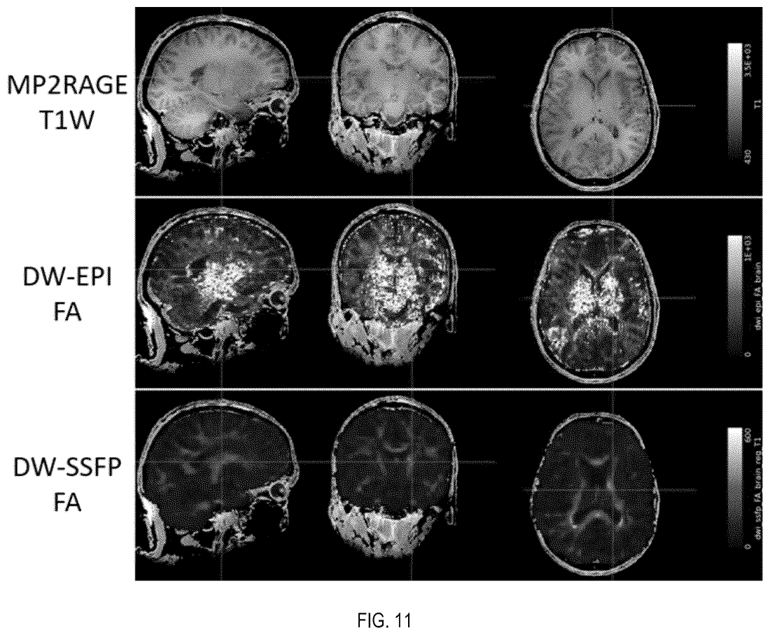

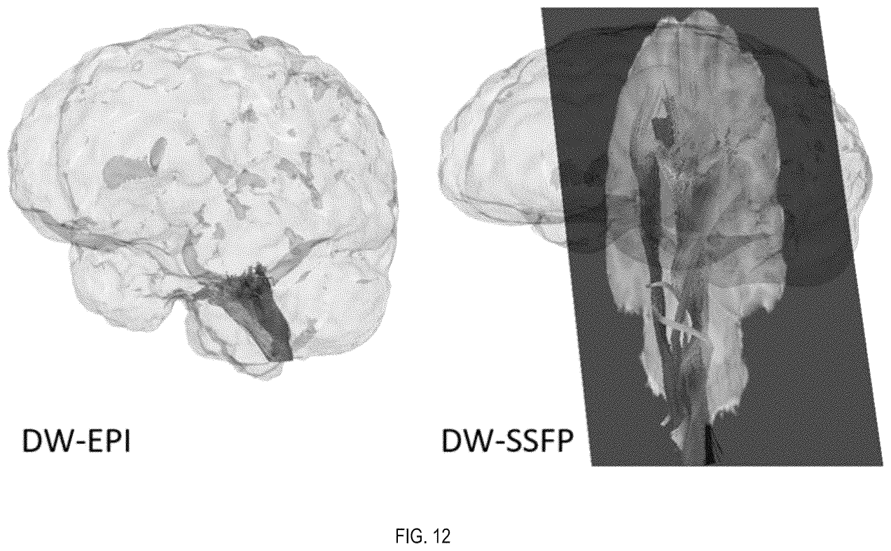

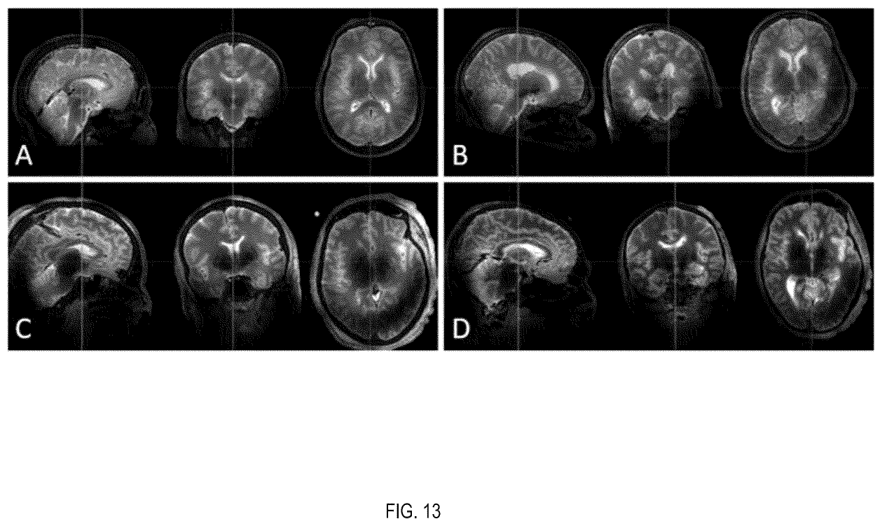

Various embodiments may achieve the following results. Results from one representative specimen (age=82, gender=F) is shown in FIGS. 10-12. All four specimens (average age=72, 1 female) are shown in FIG. 13 for T2W images. The reduced geometric distortion of the DW-SSFP sequence was demonstrated in the sagittal view of b0 images (FIG. 10). The signal reduction from the susceptibility effect was minimum in the DW-SSFP sequence due to the short echo shift. In this figure, the RF nonuniformity from 180° RF pulses of the DW-EPI sequence reduced the signal at the head center region. The reduced signal at the head center resulted in noisy and corrupted FA estimates in FIG. 11. In contrast, the signal at the head center region was uniform and hence FA was not corrupted in the DW-SSFP sequence. Furthermore, the reduced geometric distortion in the DW-SSFP sequence enabled a good tracking of the corticospinal tracts which were not well detected in the DW-EPI sequence (FIG. 12). The signal void at the head center was also observed in the T2W-SPACE images which were obtained from refocused echoes (FIG. 13). Interestingly, the signal nonuniformity was worse with the Universal RF pulse of the PTX than the STX RF pulse.

FIG. 10 shows a comparison of b0 images between the DW-EPI and DW-SSFP sequences in reference to the T1W image in three orthogonal planes. The geometric distortion is clearly shown in the sagittal view (the first columns). The RF nonuniformity effect in the DW-EPI sequence resulted in signal void at the head center region.

FIG. 11 shows a comparison of FA maps from the DW-EPI and DW-SSFP sequences. The pseudo-colored FA maps were overlaid on the T1W images in three orthogonal planes. The head center region was corrupted due to the signal void in the DW-EPI sequence, which was not seen in the DW-SSFP sequence.

FIG. 12 shows a comparison of corticospinal tracts from the DW-EPI and DW-SSFP sequences. The severe geometric distortion at the brain stem terminated the tracts in the DW-EPI sequence. In contrast, the corticospinal tracts were successfully tracked in the DW-SSFP sequence.

FIG. 13 shows T2W SPACE images acquired from four cadaveric cephalous specimens. The two specimens in the upper row (A and B) were scanned with a STX coil, while the other two specimens in the bottom row (C and D) were scanned with the PTX coil using the Universal RF pulse. The signal void due to the RF nonuniformity were more pronounced at the PTX images, which suggested that the universal RF pulse might not be effective when the cadaveric specimens were 4° C. in temperature.

In some implementations, the reduction of signals at the center of the specimens in DW-EPI and T2W-SPACE sequences was less pronounced in healthy volunteers. This may suggest that the B1+ field was altered by the specimen's lower temperature. Diffusion-weighting b value and diffusivity depend on relaxation times and flip angle in the DW-SSFP sequence. While the DW-SSFP sequence provides valid and enhanced FA and tracts, it is necessary to address the motion effects seen in in vivo scans. The motion sensitivity can be reduced by using a flow-compensated diffusion gradient and motion navigator.

In some implementations, the DW-SSFP sequence with UTE was effective in reducing the RF nonuniformity and geometric distortion in diffusion imaging at 7T. This advantage of the DW-SSFP sequence contributed to significantly improved estimates of FA over the whole brain and successful tracking of corticospinal tracts.

### Embodiment Set III: Normalization of Diffusion Weighting b Value in DW-SSFP MRI

The present disclosure describes various embodiments for enhancing DW-MRI using SSFP with normalization of diffusion weighting b value. In the present disclosure, the diffusion weighting b value may be referred as a diffusion encoding factor.

In some implementations, in DW-SSFP MRI, it has been noted that the diffusion weighting varies on diffusion encoding direction at the same b value. This phenomenon is negligible in scanning Ex Vivo samples, but it is pronounced in scanning In Vivo objects such as human brain and knee. This phenomenon results in a wrong estimation of the diffusion direction of the target tissue. At this time, this phenomenon has not yet been explained theoretically. There was a correction effort to normalize the overall image intensity of diffusion-weighted images in the diffusion encoding direction. Here, a new method of correcting the variation of the diffusion weighting is introduced.

Various embodiments may include a portion or all of the following features. The variable diffusion weighting can be corrected by normalizing the effective b value in each diffusion weighting direction rather than normalizing the image intensity. This can be achieved by use of a reference signal of a region-of-interest (ROI) within the object or from a separate reference sample outside the object. The mean image intensity of the ROI, Sᵢ, with an effective diffusion weighting bᵢ at a diffusion encoding direction i, can be described as

$${S}_{l} = {S}_{0} {e}^{- {b}_{i} D} , \qquad [ 1 ]$$

where S₀ is the signal in the absence of diffusion weighting, i.e., b=0, and D is the mean diffusivity. When taking a mean value of Sᵢ for bᵢ>0 as Sₘₑₐₙ with an applied b value as b_{ref}, Sₘₑₐₙ can be written as:

$${S}_{mean} = {S}_{0} {e}^{- {b}_{ref} D} . \qquad [ 2 ]$$

From the above two equations, the effective b value, bᵢ, can be obtained as:

$${b}_{i} = {b}_{ref} \frac{ln ( {S}_{i} ) - ln ( {S}_{0} )}{ln ( {S}_{mean} ) - ln ( {S}_{0} )} . \qquad [ 3 ]$$

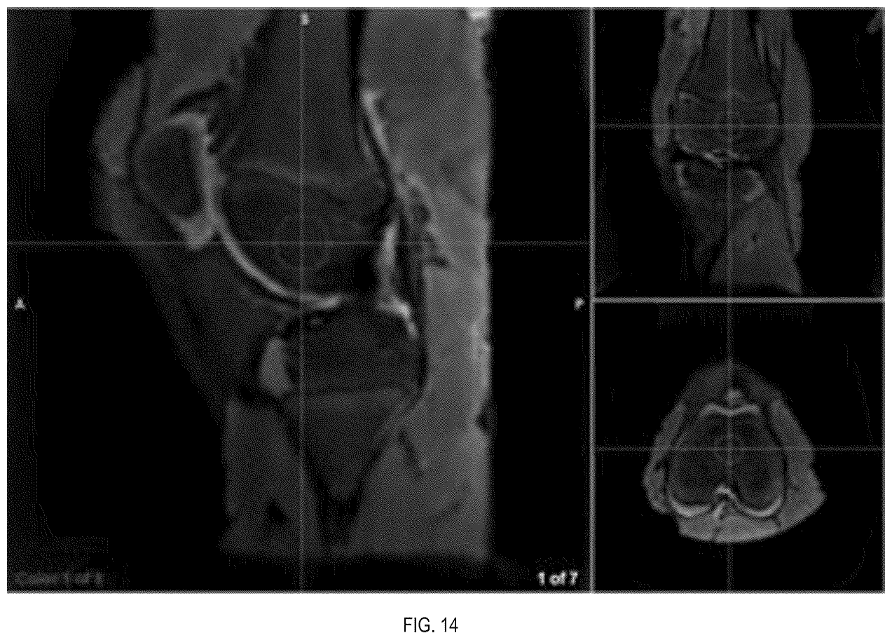

In some implementations, the method was applied to an Ex Vivo and In Vivo knee DW-SSFP MRI with an ROI shown in FIG. 14. FIG. 14 shows a ROI placed on a bone with an expected isotropic diffusion at the bone marrow for a porcine Ex Vivo knee.

In some implementations, the effective b values were estimated with the correction factor on both objects as shown in Tables 2 and 3. The variation of the effective b values was increased at an elevated diffusion weighting with the Ex Vivo samples and it was severely pronounced in an In Vivo scan.

TABLE 2
Correction factor and effective b values when b_{ref} =
800 for the Ex Vivo knee with TR = 15 ms

| Diffusion direction number | 1 | 2 | 3 | 4 | 5 | 6 |
|---|---|---|---|---|---|---|
| Correction factor | 1.011 | 0.986 | 1.009 | 1.010 | 0.999 | 0.988 |
| Effective b | 809 | 789 | 807 | 808 | 798 | 791 |

TABLE 3
Correction factor and effective b values when b_{ref} =
800 for the Ex Vivo knee with TR = 20 ms

| Diffusion direction number | 1 | 2 | 3 | 4 | 5 | 6 |
|---|---|---|---|---|---|---|
| Correction factor | 1.030 | 0.995 | 1.017 | 1.005 | 0.991 | 0.963 |
| Effective b | 824 | 796 | 813 | 804 | 793 | 771 |

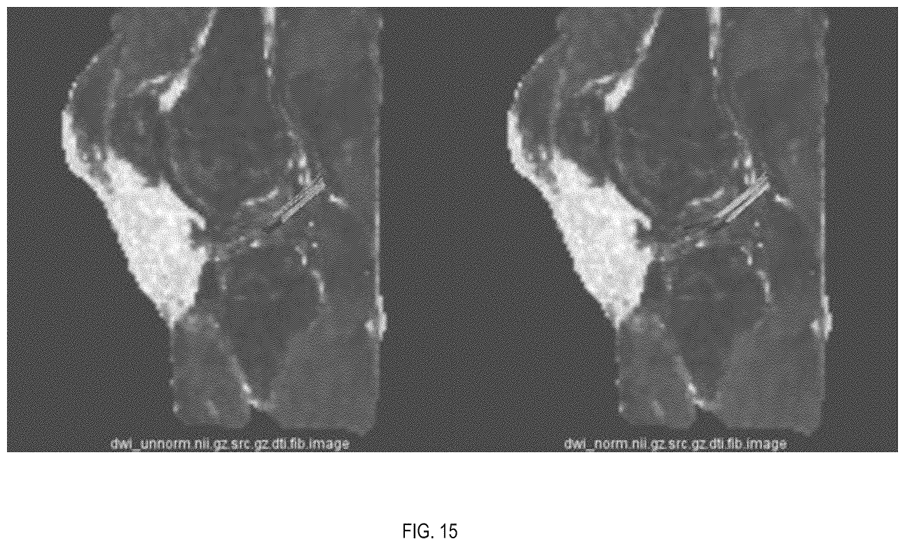

FIG. 15 shows track rendering at ACL (anterior cruciate ligament) of the Ex Vivo knee for the unnormalized (left pane) and the normalized (right pane) b values at TR=15 ms. Normalization improved the eigen vector directions resulting in an increased number of tracks to 9689 from 8771.

In various embodiments, a diffusion weighting gradient table may be provided as an extensible markup language (XML) file that can be designed for any specific diffusion vector. In some implementations, a spiral trajectory may be provided as an XML file as well.

In some implementations, a trajectory XML file may define an image size, a resolution, and/or other gradient factors for the data sampling. This file may be designed using a custom-made Matlab program. This trajectory file may also be used in image reconstruction, which, for non-limiting example, may be achieved by using a tool (e.g, Berkeley Advanced Reconstruction Toolbox (BART)) in reconstructing the non-Cartesian (or non-rectangular) trajectory such as the spiral trajectory.

In some implementations, a diffusion vector table may be for 6 vector directions and it can be extended to any number of directions, wherein the vector direction of 6 may serve a minimum number required for diffusion tensor imaging or DTI. For a non-limiting example, an XML file for a vector table may be as below.

```
<ExternalGradWaveform CoordinateSystem=“prs” Normalisation=“none”
NumberOfBhigh=“6” NumberOfBzero=“1” NumberOfDirections=“7”>
  <Shot Amp=“0” ID=“1” Phase=“1” Read=“1” Slice=“1”/>
  <Shot Amp=“1” ID=“2” Phase=“0” Read=“1” Slice=“1”/>
  <Shot Amp=“1” ID=“3” Phase=“0” Read=“−1” Slice=“1”/>
  <Shot Amp=“1” ID=“4” Phase=“1” Read=“0” Slice=“1”/>
  <Shot Amp=“1” ID=“5” Phase=“1” Read=“0” Slice=“−1”/>
  <Shot Amp=“1” ID=“6” Phase=“1” Read=“1” Slice=“0”/>
  <Shot Amp=“1” ID=“7” Phase=“1” Read=“−1” Slice=“0”/>
</ExternalGradWaveform>
```

As another non-limiting example, an XML file for a vector table of 24 directions may be as below.

```
<ExternalGradWaveform CoordinateSystem=“prs” Normalisation=“none”
NumberOfBhigh=“24” NumberOfBzero=“2” NumberOfDirections=“26”>
  <Shot Amp=“0” Phase=“1” Read=“1” Slice=“1”/>
  <Shot Amp=“1” Phase=“−0.2161” Read=“0.84182” Slice=“0.49461”/>
  <Shot Amp=“1” Phase=“−0.12482” Read=“−0.87398” Slice=“0.46965”/>
  <Shot Amp=“1” Phase=“0.97002” Read=“0.11098” Slice=“0.21621”/>
  <Shot Amp=“1” Phase=“−0.31183” Read=“−0.84769” Slice=“−0.42915”/>
  <Shot Amp=“1” Phase=“0.54523” Read=“0.21988” Slice=“−0.80894”/>
  <Shot Amp=“1” Phase=“0.42603” Read=“0.90295” Slice=“−0.056432”/>
  <Shot Amp=“1” Phase=“0.37467” Read=“0.15451” Slice=“0.91419”/>
  <Shot Amp=“1” Phase=“0.11624” Read=“0.53318” Slice=“−0.83798”/>
  <Shot Amp=“1” Phase=“−0.76234” Read=“0.045191” Slice=“−0.64559”/>
  <Shot Amp=“1” Phase=“−0.60895” Read=“−0.62553” Slice=“0.48774”/>
  <Shot Amp=“1” Phase=“−0.79559” Read=“−0.5985” Slice=“−0.093982”/>
  <Shot Amp=“1” Phase=“0.65872” Read=“−0.61228” Slice=“−0.43726”/>
  <Shot Amp=“1” Phase=“−0.94504” Read=“0.31684” Slice=“0.080649”/>
  <Shot Amp=“1” Phase=“−0.80465” Read=“0.14154” Slice=“0.57663”/>
  <Shot Amp=“1” Phase=“0.10681” Read=“−0.99425” Slice=“−0.00818”/>
  <Shot Amp=“1” Phase=“−0.36752” Read=“0.78238” Slice=“−0.50281”/>
  <Shot Amp=“1” Phase=“0.65294” Read=“0.48439” Slice=“0.58226”/>
  <Shot Amp=“1” Phase=“−0.59197” Read=“0.80568” Slice=“−0.021028”/>
  <Shot Amp=“1” Phase=“−0.095665” Read=“−0.56139” Slice=“−0.82201”/>
  <Shot Amp=“1” Phase=“−0.086433“ Read=”−0.026028” Slice=“0.99592”/>
  <Shot Amp=“1” Phase=“0.38891” Read=“−0.37031” Slice=“−0.84357”/>
  <Shot Amp=“1” Phase=“0.9211” Read=“0.25602” Slice=“−0.2933”/>
  <Shot Amp=“1” Phase=“0.38351” Read=“−0.38474” Slice=“0.83958”/>
  <Shot Amp=“1” Phase=“0.78792” Read=“−0.47643” Slice=“0.39013”/>
  <Shot Amp=“0” Phase=“1” Read=“1” Slice=“1”/>
</ExternalGradWaveform>
```

Various embodiments in the present disclosure may address challenges encountered by traditional diffusion-weighted MRI, particularly at higher magnetic fields such as the 7 Tesla MRI environment. For example, these challenges include: geometric distortion, wherein the strong magnetic field may cause geometric distortions in the images, making them appear stretched or twisted; and/or non-uniform image brightness, wherein variations in radio-frequency (RF) signal transmission result in uneven image brightness across the field-of-view.

### Embodiments: UTE-Based DW-SSFP Sequence to Acquire MRI Images of Prostate

Another exemplary embodiment may include using a UTE-based DW-SSFP sequence to acquire diffusion images of prostate.

In some implementations, a diffusion imaging is one of the main protocols for the prostate cancer diagnosis. The conventional 2-dimension EPI diffusion imaging sequence, i.e., EP2D diffusion, has a limitation of low spatial resolution in the slice direction, which can lead to an inaccurate reading of the prostate cancer. In addition, the slice coverage is limited by the number of slices and often this could lead to an insufficient slice coverage of the prostate and its neighbor region.

The UTE-based diffusion-weighted SSFP (DW-SSFP) is a full 3-dimensional acquisition method, providing a good spatial resolution and coverage in all three axes. In some implementations, the DW-SSFP sequence may be compared with the conventional EP2D diffusion sequence for the mean diffusivity of prostate tissue.

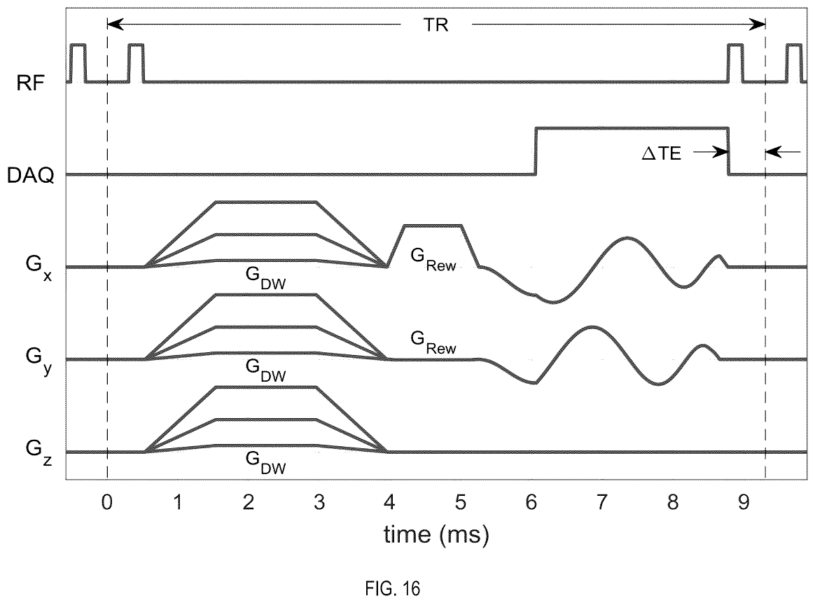

In a non-limiting example, the diffusion weighting was applied to all three axes at the same time to measure the mean diffusivity, referring to FIG. 16. Three diffusion weightings of b=1, 218, and 493 may be applied. The scan parameters of DW-SSFP may include voxel size=1 mm³ isotropic, field-of-view=224 mm, TR=9.3 ms, flip angle=20°, and scan time=5:45.

FIG. 16 shows a DW-SSFP sequence diagram. A diffusion-weighting gradients (G_{DW}) is applied on all three gradient axes. G_{Rew} denotes the rewind gradient of the readout gradient. ΔTE denotes the echo shift time. A binomial water selection RF pulse was used to suppress the fat-induced image artifacts

Merely for the purpose of comparison, a conventional EP2D diffusion may be obtained, wherein the scan parameters may include inplane pixel size=0.9×0.9 mm², slice thickness=3.5 mm, field-of-view=200 mm, number of slices=20, b=50, 400, and 800, TR=3 s, TE=57 ms, and scan time=3:29.

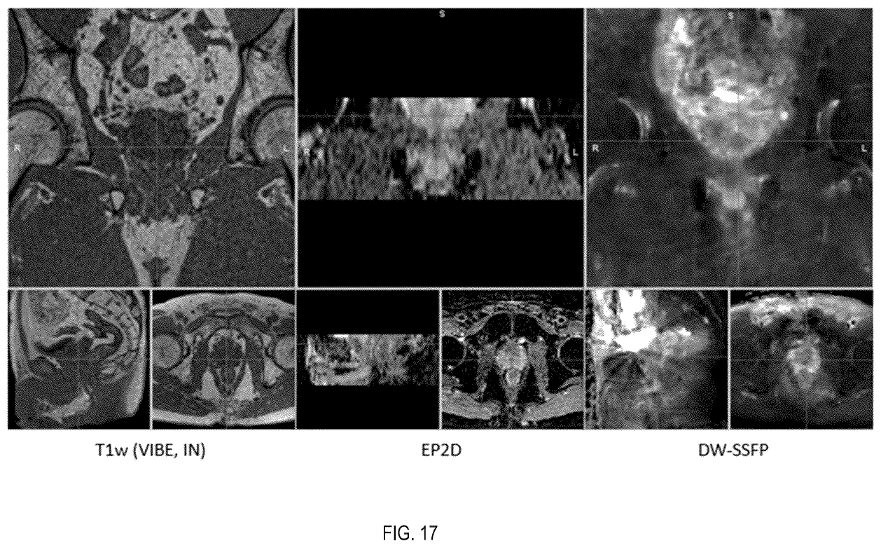

Referring to FIG. 17, a healthy volunteer may be scanned at 3T with a spine and body-matrix RF coils. The EP2D may have a poor inplane resolution in the slice direction, i.e., head-to-foot direction, while DW-SSFP showed isotropic spatial resolution in all three directions. In addition, the slice coverage of the EP2D may be limited in the slice direction, while the DW-SSFP may cover the whole pelvis area. This advantages of DW-SSFP over the conventional EP2D may be useful in screening a wider region beyond the prostate tissue.

FIG. 17 shows three orthogonal planes of three different imaging methods are compared. The left panel is a T1-weighted anatomical water-selected image. The middle and right panels are mean diffusivity obtained using the EP2D diffusion sequence and the UTE-based 3-dimensional DW-SSFP sequence, respectively. FIG. 17 shows that the spatial resolution on the coronal plane is quite different between EP2D and DW-SSFP results.

### Embodiments: UTE-Based Magnetization Transfer MRI to Acquire MRI Images

Various embodiments in the present disclosure may include using UTE-based magnetization transfer MRI to acquire MRI images. In some implementations, the UTE-based magnetization transfer MRI may include using UTE-based magnetization saturation MRI; and/or asymmetric magnetization transfer ratio of the UTE-based magnetization saturation MRI may be used to obtain MRI images, for example, for mapping myelin in a brain (brain myelin). Myelin mapping of the brain is important for studying brain disease, development, and aging.

In some implementations, protons of macromolecules like myelin were challenging to be mapped via normal MRI because their T2 relaxation time is too short. Myelin water imaging may map myelin location by measuring water molecules trapped between myelin layers.

In some implementations, magnetization transfer ratio (MTR) MRI may be used to map myelin by measuring the influence of macromolecule protons (invisible) on surrounding water (visible), and regular MTR measures macromolecules. Inhomogeneous (ihMTR) is selective for myelin; and/or Ultrashort echo time (UTE) MRI captures myelin by directly measuring very short T2 myelin protons using ultrashort pulses.

Myelin mapping has a great importance in biomedical research, leading to more advanced biomedical diagnostics and treatment. For example, myelin mapping may serve as an important role in understanding the role of myelin in brain development, aging, plasticity and degeneration, and to monitor the progress and treatment of diseases like multiple sclerosis. However, field inhomogeneity may cause noise and heat from RF pulse, causing patient discomfort. Myelin water imaging may include external factors such as inflammation or edema, which may reduce selectivity for myelin.

In various embodiments in the present disclosure, UTE and MTR MRI are combined, a UTE-based ihMTR, which is more sensitive and selective for myelin, leading to better results in subcortical and cortical grey matter, which has less myelin than white matter.

In some implementations, T2* relaxation time of myelin lipid powder was reported to 0.33 ms and an inversion-recovery UTE was reported to map myelin directly. In this aspect, relaxation-based myelin mapping methods with a longer TE can be limited in detecting the whole myelin. Magnetization transfer ratio (MTR) has been reported to represent the myelin content. Recently, inhomogeneous MTR has been used to make MTR more specific to myelin. Furthermore, a UTE-based inhomogeneous MTR has been reported to be more sensitive to the myelin content compared to the conventional MRI. Therefore, myelin mapping based on the UTE-based MTR has been developed with more advanced features.

In some implementations, the magnetization saturation depends on the offset frequency as in ihMTR and Chemical Exchange Saturation Transfer (CEST). In ihMTR, it compares a magnetization saturation level between the same polarity and mixed polarity of the offset frequency. There was a significant saturation difference between the positive and negative offset frequencies, but insignificant difference between the same and mixed offset frequencies. Therefore, a myelin mapping is obtained by asymmetry between the signal obtained with positive (M_{P}) and negative offset frequencies (M_{N}): Asm2MTR=(M_{P}−M_{N})/(M_{P}+M_{N})/2*100.

In some implementations, the signal without the magnetization saturation, i.e., M_{OFF}, is obtained, Asym3MTR can be obtained as Asm3MTR=(M_{P}−M_{N})/M_{OFF}*100 and a mean MTR can be obtained as MeanMTR=[M_{OFF}−(M_{P}+M_{N})/2]/M_{OFF}*100.

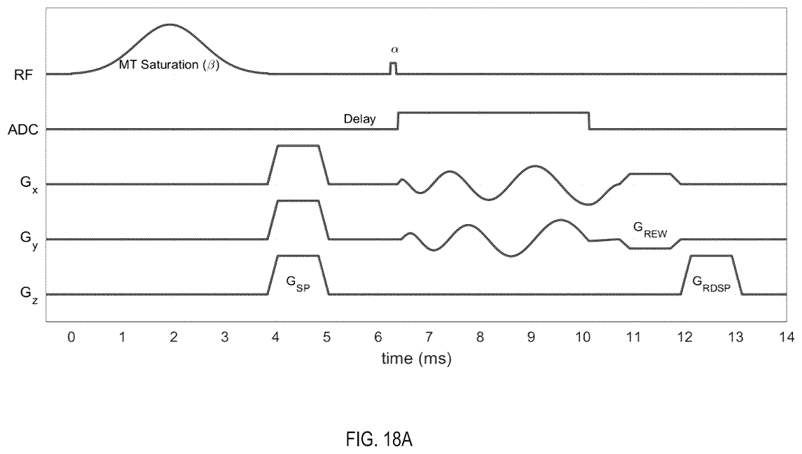

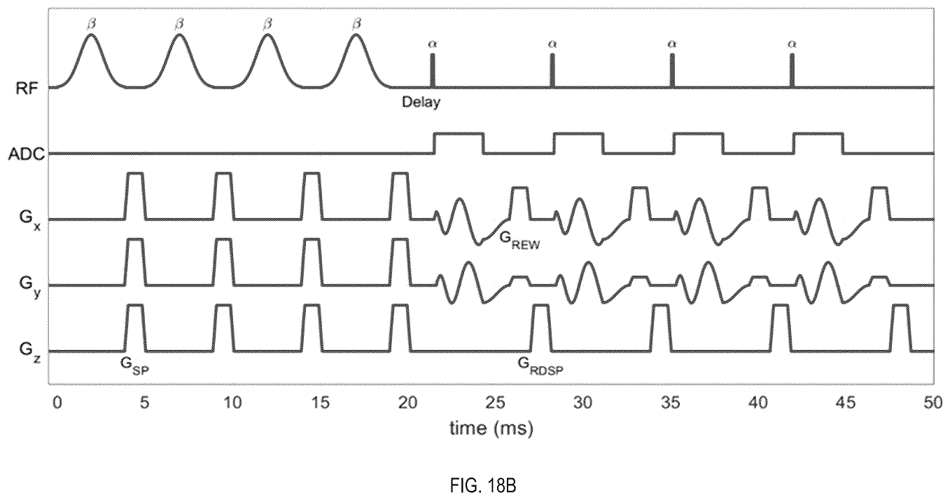

In some implementations referring to FIG. 18A, a 3D UTE sequence has been expanded to magnetization saturation by adding a Gaussian saturation RF pulse before the excitation RF pulse.

FIG. 18A shows a diagram of the basic components of the MTR sequence. The MT saturation RF may be a Gaussian RF (Duration=3840 μs, and flip angle=β). A spoiler gradient, G_{SP}, was applied after the magnetization saturation RF pulse. There was a variable delay, i.e., Delay, between the magnetization saturation spoiler gradient and the excitation RF pulse to control the magnetization transfer time. ‘ADC’ is the time window for data acquisition or sampling. After the readout gradient, a rewind gradient, i.e., G_{REW}, was applied on the same readout axes after the readout. Another spoiler gradient, i.e., G_{RDSP}, was applied to an orthogonal direction to the readout plane for more reliable spoiling.

In some implementations referring to FIG. 18B, the magnetization saturation is achieved by applying a train of the saturation RF pulses and spoiling gradient pulses to enhance the magnetization saturation at a controlled RF safety level. After the magnetization saturation RF pulses, a series of readouts is followed to speed up the scan. One block of the sequence diagram is shown in FIG. 18B for 4 saturation RF pulses and 4 readouts.

FIG. 18B shows an MTS sequence diagram with 4 magnetization saturation RF pulses of the positive offset frequency and 4 readouts. The saturation RF pulse is a Gaussian shape with a flip angle β and the readout RF pulse is a rectangular pulse with a flip angle α. There is a spoiler gradient (G_{SP}) after each Gaussian RF pulse. There is a variable delay after the spoiler gradient until the readout RF pulse. The readout gradient is rewound (G_{REW}) followed by a spoiler gradient (G_{RDSP}) on a orthogonal axis to the readout gradients.

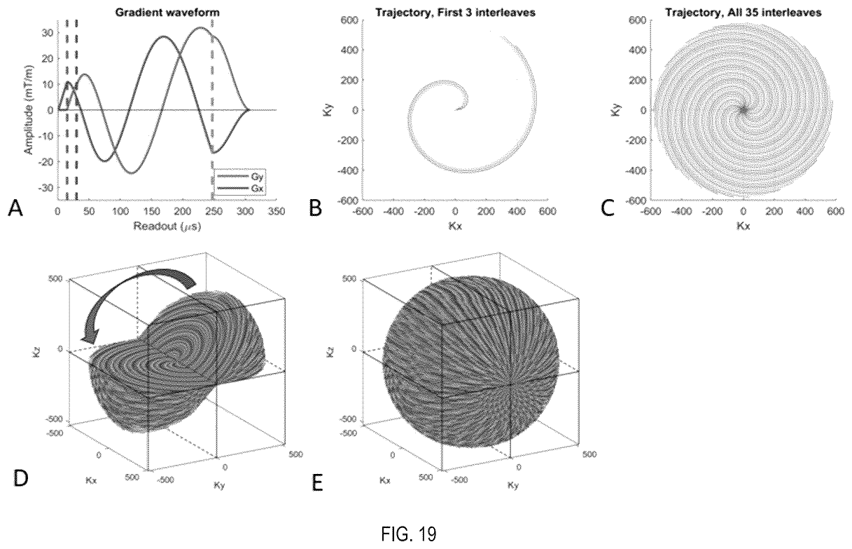

In some implementations, the readout gradient waveform and its trajectory schematics on the K-space are shown in FIG. 19. In FIG. 19, a readout gradient waveform of the spiral shape and its trajectory on the Kₓ and K_{y} plane (B and C). The spiral disc is rotated to fill the 3D K-space (D and E). The spiral shape in B may be a spiral out shape.

In various embodiments in the present disclosure, a ‘spiral’ trajectory may be a variation (or a subcategory) of spiral trajectory groups, as winding hybrid interleaved radial lines (WHIRL) trajectory, which may include a hybrid of radial and spiral trajectories to enhance the UTE effect. In some implementations, a spiral trajectory may start as a radial trajectory at the K-space center and then transit into spiral trajectory. For example, a hybrid trajectory is shown partially at FIG. 19 (A), wherein the initial rise of the spiral waveform is a straight line, i.e., radial trajectory.

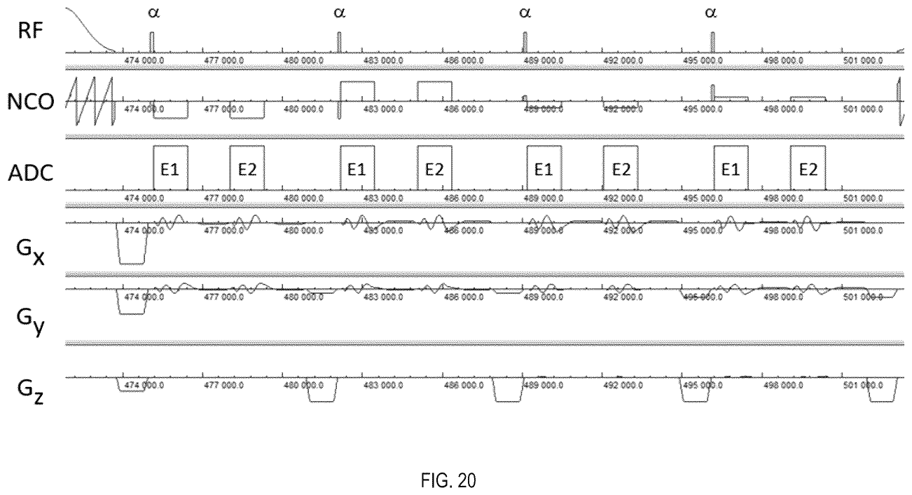

In some implementations referring to FIG. 20, the UTE-sequence can be expanded to obtain multiple echoes for the case of acquiring 2 echoes. FIG. 20 shows a sequence diagram with two echoes of E1 and E2 in each excitation by an RF pulse of a flip angle α. There are 4 excitations after the magnetization saturation to expedite the scan time. ‘NCO’ stands for ‘numerical crystal oscillation’ and shows the phase information of the RF pulses and ADC.

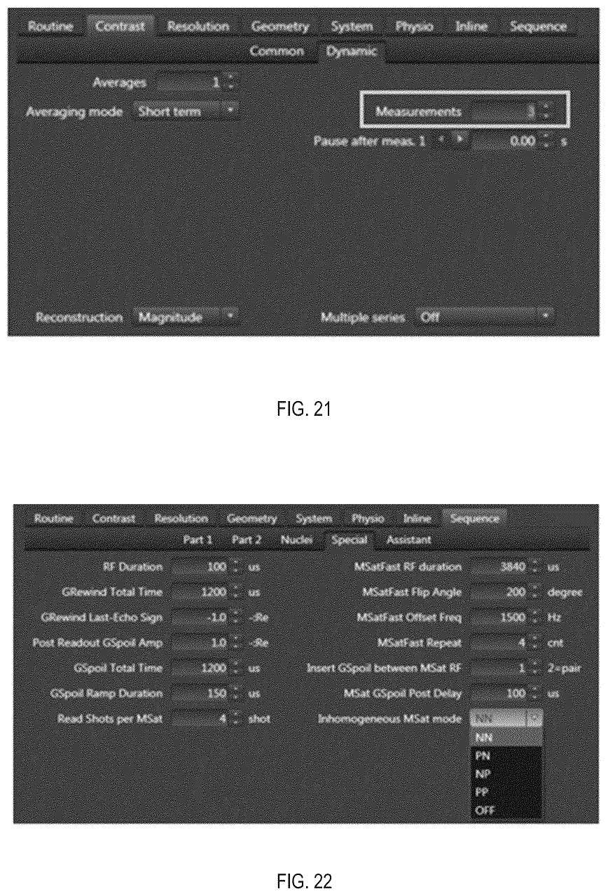

In some implementations referring to FIG. 21 and FIG. 22, the sequence parameters for the UTE-based MTR sequence may be specified using the GUI cards at the MRI console. The measurement numbers in FIG. 21 can be used to select the MTR contrast types. The frequency offset polarity for the measurement number of 1, 2, and 3 can be chosen as explained in Table 4 using the scan parameter ‘Inhomogeneous MSat mode’ in the ‘Special’ GUI card shown in FIG. 22.

FIG. 21 shows a setting of measurement numbers at the MRI console. The measurement numbers are selectable from 1 to 5. FIG. 22 shows a setting of the sequence parameters which are specific to the customized UTE-based magnetization saturation sequence. The number of magnetization saturation and excitation RF pulses can be specified here. The offset frequency polarity for the inhomogeneous magnetization saturation is selected when the measurement number is 1, 2, and 3 as listed in Table 4.

Table 4 lists configurations of the frequency offset polarity of the magnetization saturation RF pulses depending on the measurement numbers. The polarity marked as ‘QR’ is selectable among the polarities listed in the QR column which is chosen from a GUI at the MRI console shown in FIG. 22.

TABLE 4
Configuration of the frequency offset polarity of the magnetization
saturation RF pulses depending on the measurement numbers

| Measurement No | 1 | 2 | 3 | 4 | 5 | QR |
|---|---|---|---|---|---|---|
| 1 | QR | | | | | NN, PN, NP, PP, OFF |
| 2 | NN | QR | | | | NN, PN, NP, PP, OFF |
| 3 | PP | QR | OFF | | | NN, PN, NP |
| 4 | PP | NN | PN | OFF | | |
| 5 | PP | NN | PN | NP | OFF | |

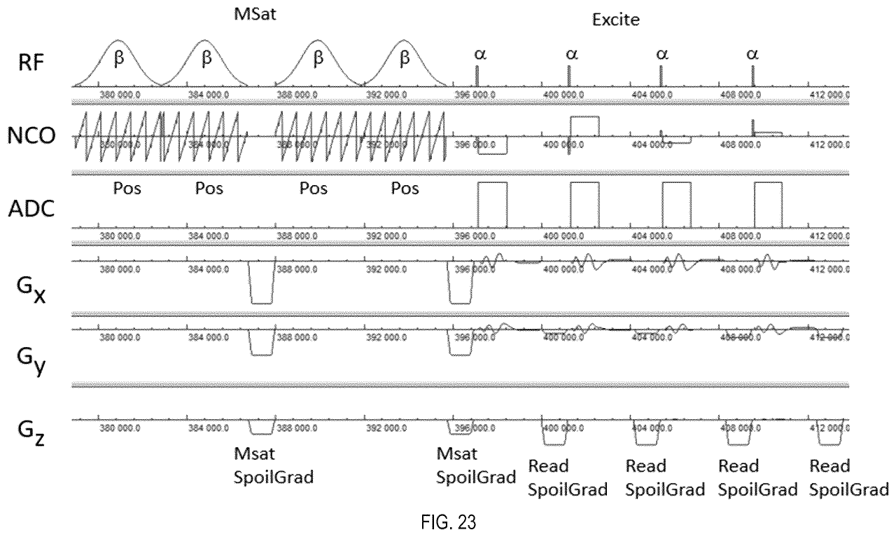

In some implementations referring to FIG. 23, the magnetization saturation is achieved by a series of RF pulses of a relatively smaller flip angle β instead of one saturation RF pulse of a large flip angle, which will be more effective in reducing the RF heating and the B1+ inhomogeneity. The number of saturation RF pulses can be set from the scan parameter ‘MSatFast Repeat’ in the ‘Special’ GUI card shown in FIG. 22.

In some implementations, the frequency offset polarity of the saturation RF pulses can be positive or negative. The magnetization saturation effect may depend on the polarity of the offset frequency. The polarity of the saturation RF pulses can be identified by the slope of the ‘NCO’ waveform in FIG. 23. Magnetization saturation RF pulses of both polarities of the frequency offset are known to be specific to the myelin. This can be implemented either by a pair of interleaved saturation RF pulses of both polarities or a combined RF pulse of both polarities. However, the combined RF pulse is expected to be restricted by the peak RF power and suffer from a nonlinear RF response. Therefore, it is chosen to use the pair of RF pulses of positive and negative polarities.

FIG. 23 shows a sequence diagram of 1 period of magnetization saturations and readouts. There are 4 magnetization saturation RF pulses of flip angle β followed by 4 excitation RF pulses of flip angle α with a readout of 1 echo in each excitation. The ‘NCO’ describes the polarity of the offset frequency. After 1 pair of saturation RF pulses a spoiler gradient is applied to all three gradient axes. The readout gradient is followed by a rewinding gradient and a separate spoiler gradient applied to an orthogonal axis to the readout plane. Both the magnetization saturation and excitation RF pulses were spoiled with a random phase, which can be recognized from the fluctuating NCO in each RF pulse. The number of magnetization saturation RF pulses and the excitation RF pulses in each period can be defined from the GUI at the MRI console as shown in FIG. 22. The spoiler gradients during the magnetization saturation are applied after a pair of magnetization saturation RF pulses, which can be changed from the special card of the MRI console shown in FIG. 22. This mode of saturation spoiler gradient pulses can simulate the dual-frequency saturation better than other options.

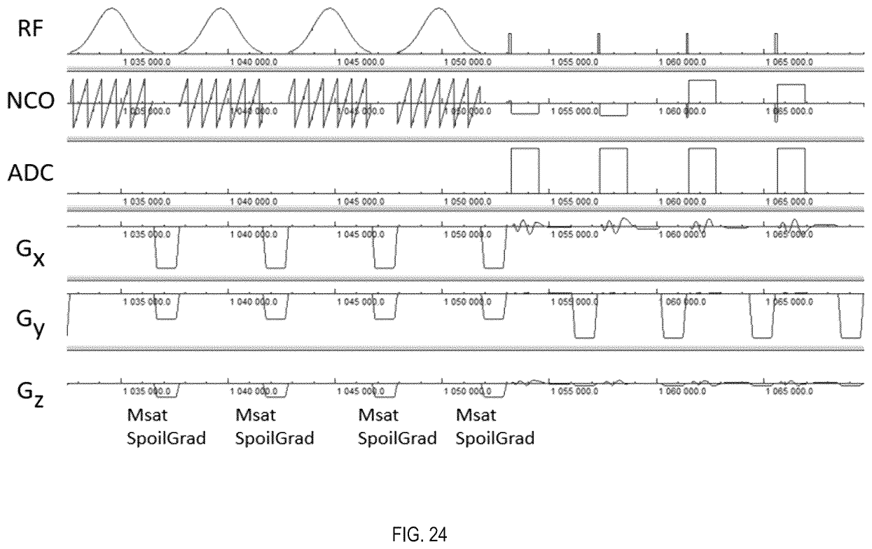

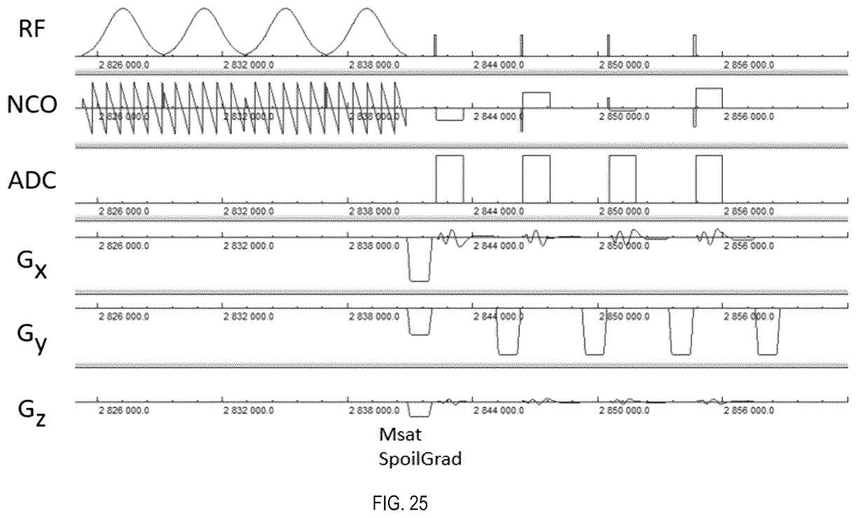

In some implementations, the saturation RF pulse is followed by a spoiler gradient pulse to enhance the saturation effect (as shown in FIG. 23). The timing of the spoiler gradient is selectable among three different modes using the parameter ‘Insert G_{Spoil} between MSat RF’ in the GUI. Three modes of inserting a spoiler gradient during the magnetization saturation are selectable as demonstrated in FIG. 23, FIG. 24, and FIG. 25 for 3 cases of ‘after each pair of saturation RF pulses’, ‘each saturation RF pulse’, and ‘after the last saturation RF pulse’, respectively.

FIG. 24 shows that spoiler gradient pulses are applied after each of the magnetization saturation RF pulse, which can be specified in the GUI at the MRI console. This configuration can increase the saturation effect at the cost of an increased scan time and nerve stimulation.

FIG. 25 shows spoiler gradient pulses are applied only after the last magnetization saturation RF pulse, which can be specified in the GUI at the MRI console. This configuration can save scan time and reduce nerve stimulation.

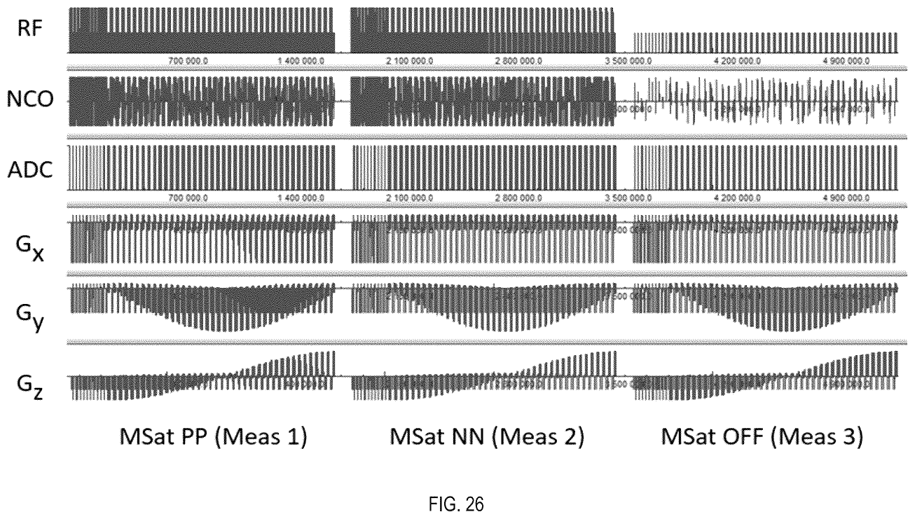

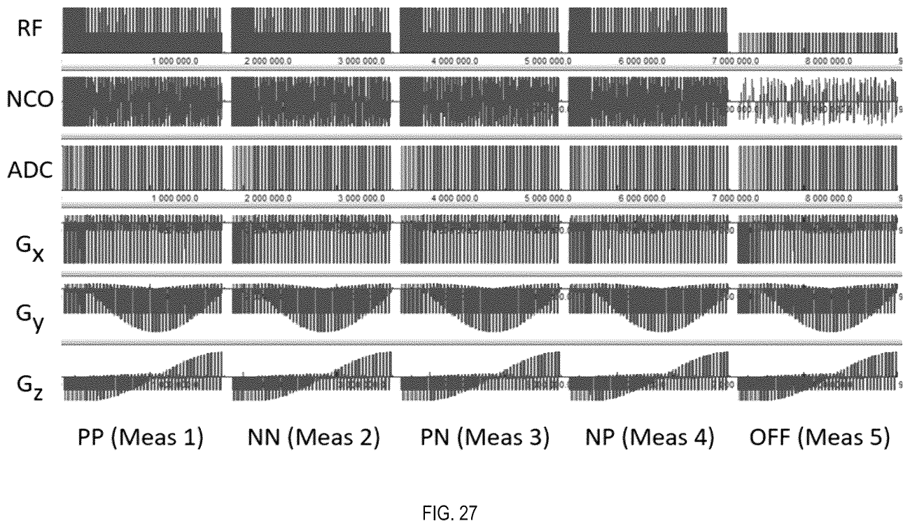

In some implementations, the polarities of the magnetization saturation RF pulses are listed in Table 4 for different measurement numbers. The pulse sequences for the measurement number of 3 and 5 are shown in FIG. 26 and FIG. 27. For example, when the measurement number is 3, the first measurement is set to a positive polarity, but the polarity of the second measurement can be specified by another scan parameter ‘Inhomogeneous MSat mode’ as listed. When the measurement number is 5, all 4 permutations of the polarities are included, and its order is fixed as shown in Table 4 and in FIG. 27.

FIG. 26 shows an overall diagram of pulse sequences for the measurement numbers of 3. The frequency offset polarity of the magnetization saturation RF pulses is defined in Table 4.

In some implementations, after each measurement there is an optional pause followed by dummy scans to reach a steady state before the excitations. This configuration is good for the magnetization transfer ratios of asymmetric and inhomogeneous-2 modes.

FIG. 27 shows an overall diagram of pulse sequences for the measurement numbers of 5. The frequency offset polarity of the magnetization saturation RF pulses is defined in Table 4. This configuration is good for the magnetization transfer ratios of inhomogeneous-3 and -4 and all other permutation of magnetization transfer ratios.

In some implementations, the MTR from a single saturation polarity may be defined as MTR=(MT_{off}−MTₒₙ)/MT_{off}×100, where MTₒₙ can be any polarity.

An asymmetric MTR can be obtained from a pair of positive and negative polarities: asymMTR=(MT_{PP}−MT_{NN})/MT_{off}×100. The asymmetric MTR can be redefined only from the pair of positive and negative polarities without the off, which will save the scan time:

$$asymMTR\_P = ( {MT}_{PP} - M {T}_{NN} ) / {MT}_{PP} \times 100.$$

$$asymMTR\_N = ( M {T}_{P P} - M {T}_{N N} ) / {MT}_{NN} \times 100.$$

An inhomogeneous MTR can be divided into three different definitions. The conventional ih4MTR is obtained from the four polarities as,

$$ih 4 MTR = [ ( M {T}_{P P} + M {T}_{N N )} - ( M {T}_{P N} + M {T}_{NP )} ] / {MT}_{off} \times 100.$$

In some implementations, the saturation effect of MT_{NN}, MT_{PN}, and MT_{NP} are similar resulting in reduced sensitivity. Therefore, two new definitions of ih2MTR and ih3MTR are introduced in this development:

$$Ih 2 MTR = [ {MT}_{PP} - ( M {T}_{PN} + M {T}_{NP} ) / 2 ] / {MT}_{off} \times 100 , and$$

$$Ih 3 MTR = [ {MT}_{PP} - ( M {T}_{NN} + M {T}_{PN} + M {T}_{NP} ) / 3 ] / {MT}_{off} \times 100.$$

In some implementations, Ih2MTR is attractive as it can save the scan time from ih4MTR as well as it is more sensitive than the conventional ih4MTR.

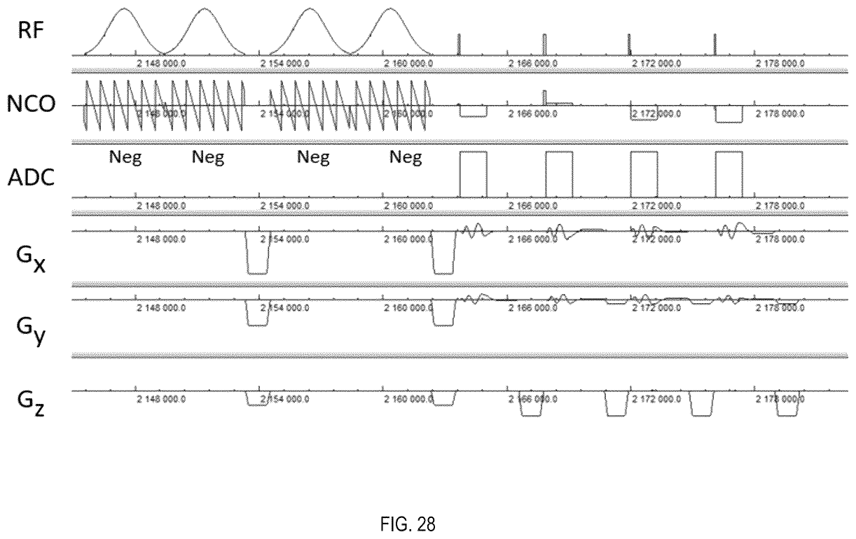

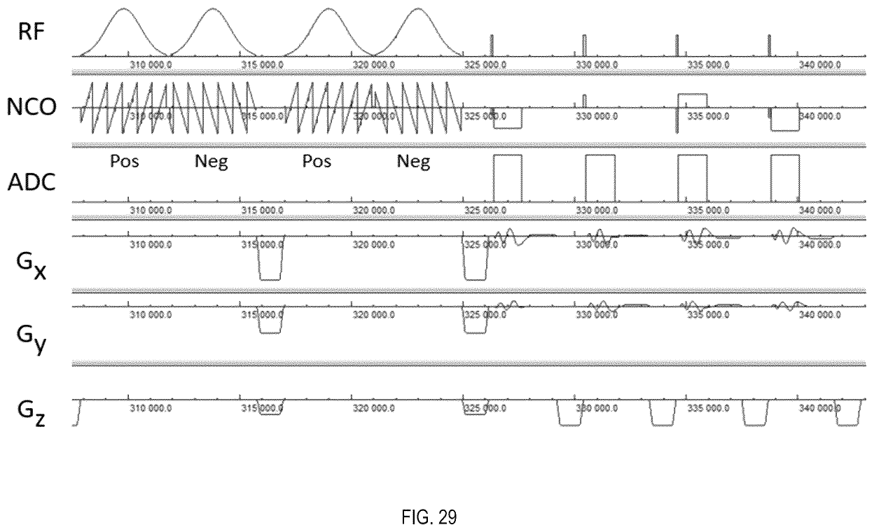

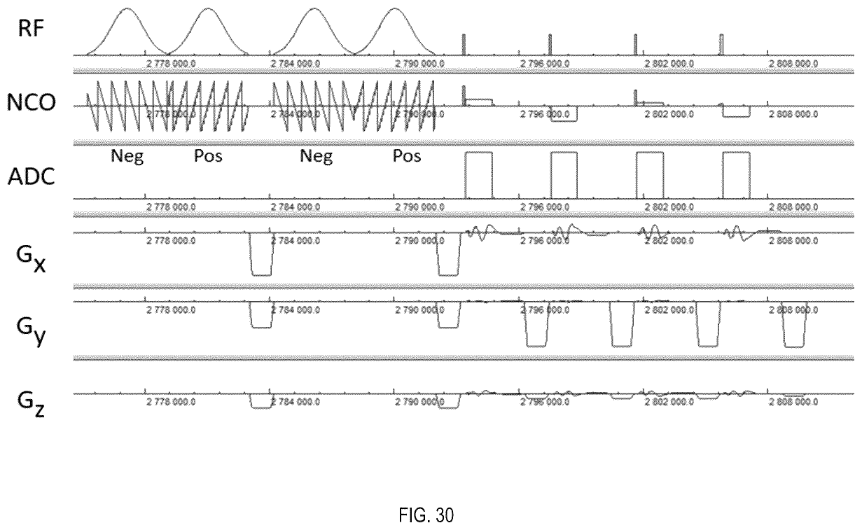

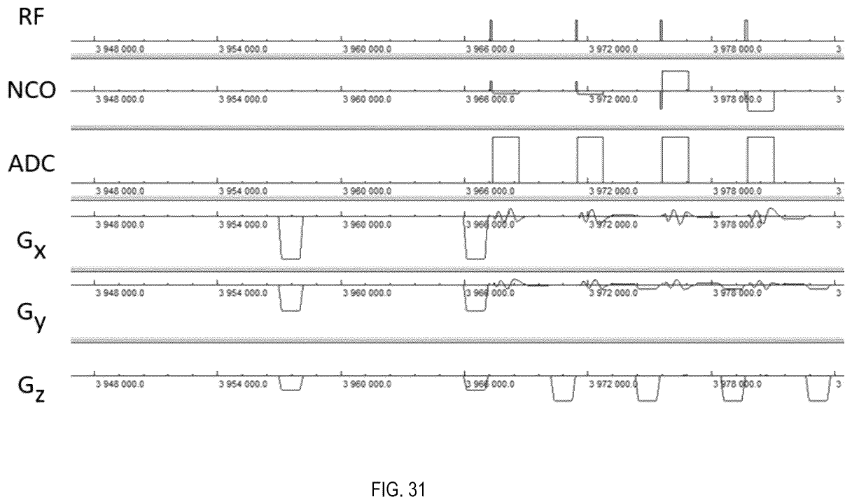

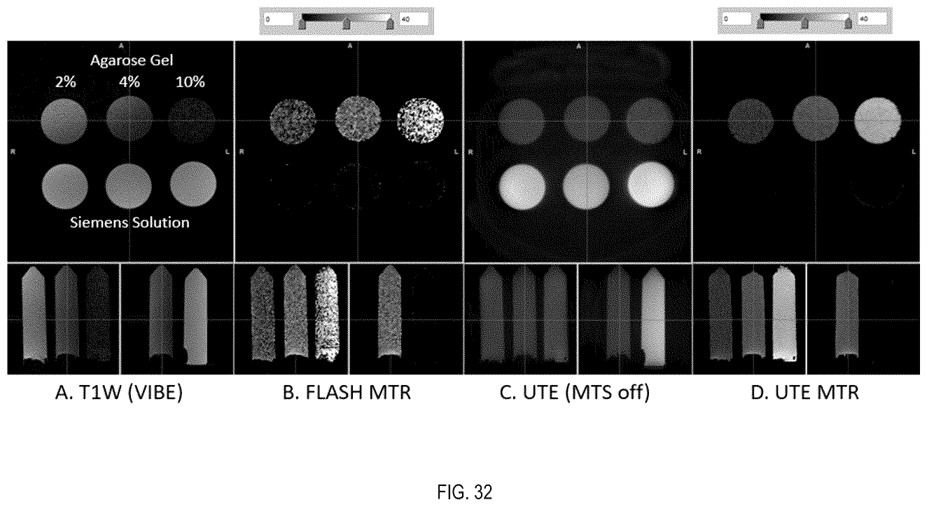

In some implementations, the sequence diagrams of different frequency offset polarities of the magnetization saturation RF pulse are shown in FIG. 28, FIG. 29, and FIG. 30 for NN, PN, and NP, respectively. The sequence without the saturation RF pulses is shown in FIG. 31.

FIG. 28 shows a variation of the offset frequency polarities of the magnetization saturation RF pulses from PP to NN. FIG. 29 shows a variation of the offset frequency polarities of the magnetization saturation RF pulses from PP to PN. FIG. 30 shows a variation of the offset frequency polarities of the magnetization saturation RF pulses from PP to NP. FIG. 31 shows that magnetization saturation RF pulses are not applied while maintaining the spoiler gradients.

In some implementations, the sequence has been evaluated on different objects and two main magnetic field of 3T and 7T MRI systems.

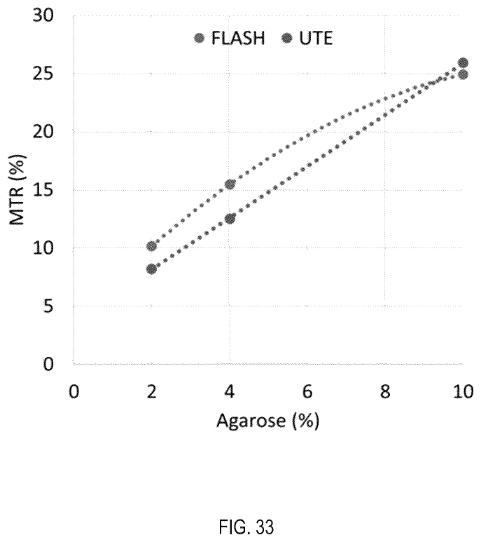

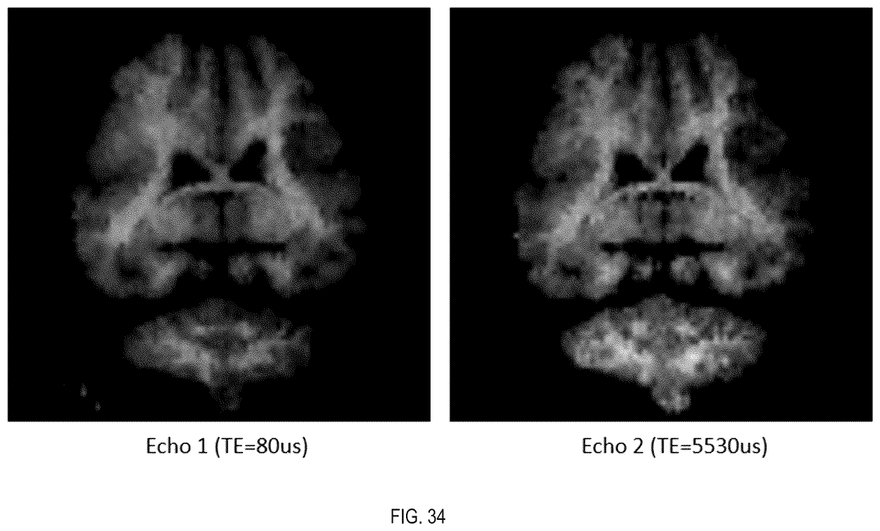

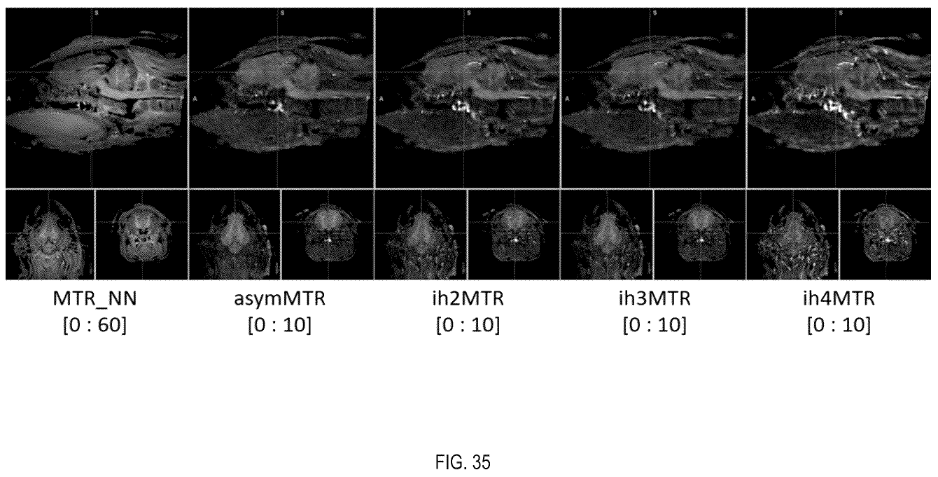

In some implementations, the UTE MTR resulted in an increased signal (FIG. 32) and a better linear regression to the agarose concentration (FIG. 33) than the FLASH MTR. The same effect has been confirmed on an Ex Vivo piglet brain sample (FIG. 34). The various MTR methods were obtained from an In Vitro piglet head using the measurement number 5 (FIG. 35).

FIG. 32 shows MR images obtained from tubes filled with solution and various concentrations of agarose gel.

FIG. 33 shows a comparison of FLASH and UTE-based MTR for the regression of MTR values in the three tubes of agarose gel. The MTR value was saturated at the 10% agarose in the FLASH-based MTR, which might be attributed to an increased fraction of a small T2 component. In contrast, the UTE-based MTR was fitted linearly as a result of its increased sensitivity to the small T2 component due to a short echo time.

FIG. 34 shows MTR maps obtained from an Ex Vivo piglet brain at two different echo times. The UTE with the short echo time resulted in a MTR map of more sensitive and less noisy than the long echo time.

FIG. 35 shows various MTR maps obtained from an In Vitro piglet at 7T. The number of measurements was 5 and hence asymmetric, inhomogeneous-2, inhomogeneous-3, and inhomogeneous-4 MTR maps were obtained from the same data set. The numbers in the bracket denote the display window range which indirectly provides the sensitivity of MTR. The offset frequency was 6000 Hz, the number of magnetization saturation RF pulses was 8 and there were 4 readout excitations in each period. In some implementations, the spinal discs were attenuated in the asymmetric and inhomogeneous MTR maps while they were included in the single MTR map such as MTR_NN.

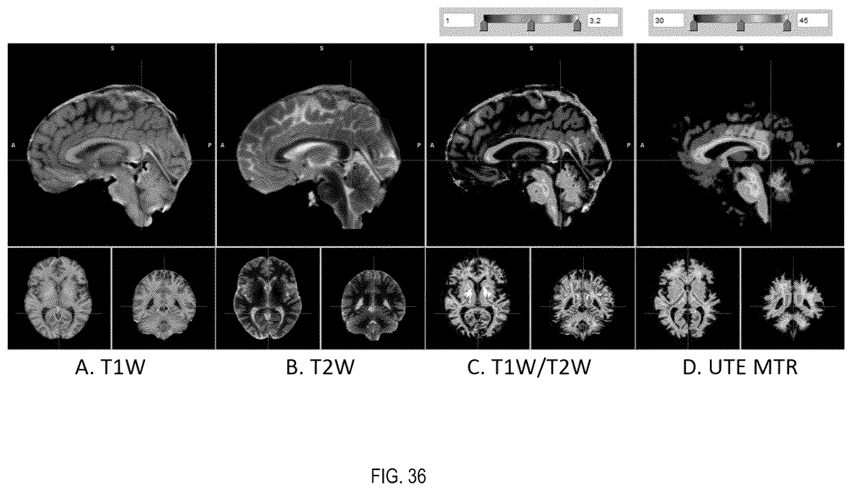

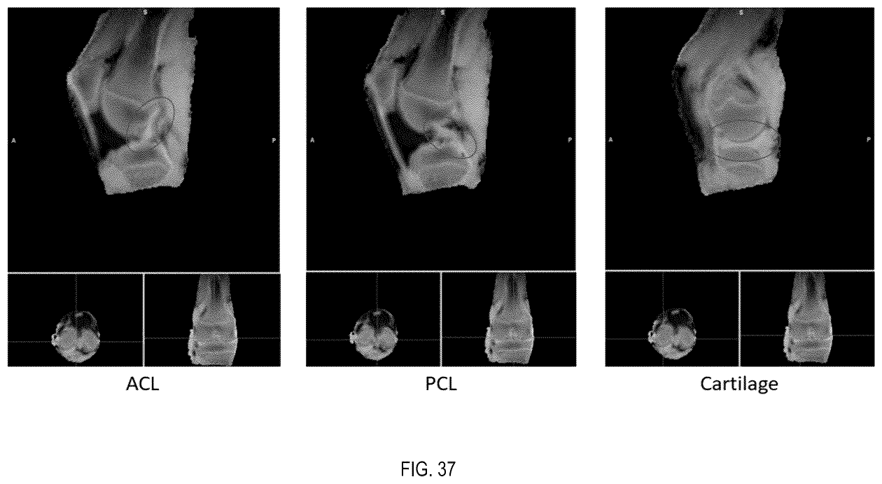

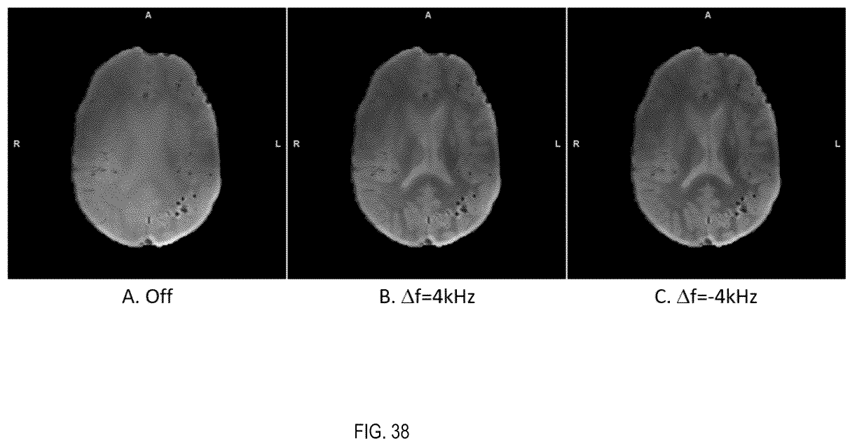

In some implementations, the MTR was evaluated using a cadaveric human head at 7T in comparison with the T1W/T2W ratio map (FIG. 36). MTR produced myelin map that is more closely correlated with a separate histology result released in a recent report. MTR was also tested on Ex Vivo porcine knee samples (FIG. 37).

FIG. 36 shows MR images and MTR maps obtained from a cadaveric head specimen at 7T. These are shown in a slice position of the corpus callosum.

FIG. 37 shows MTR maps obtained from an Ex Vivo porcine knee samples.

For another example with brain myelin mapping using asymmetric magnetization transfer ratio of UTE-based magnetization saturation MRI. For an MTS sequence as shown in FIG. 18B, some scan parameters may include: saturation offset frequency=+/−4 KHz, saturation angle of each saturation Gaussian RF=160°, readout RF angle=5°, field-of-view=216 mm, isotropic voxel size=1 mm, TR=60 ms for one block of 4 readouts, TE=0.07 ms, ADC readout time=2810 μs, acceleration=2, shots/volume=11424, and scan time for 3 magnetization saturation conditions=8:37. In some implementations, the data were collected from two cadaveric human heads (male 69 yr, female 71 yr) using a 7T MRI System with a STX RF coil of 32-channel. The cadaveric heads were kept in a refrigerator at 4° C. The data was reconstructed into images using the PICS library of the BART tool.

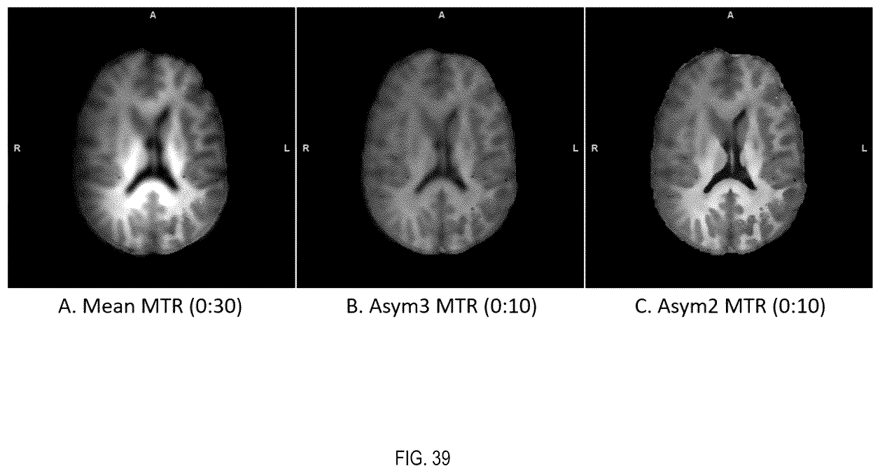

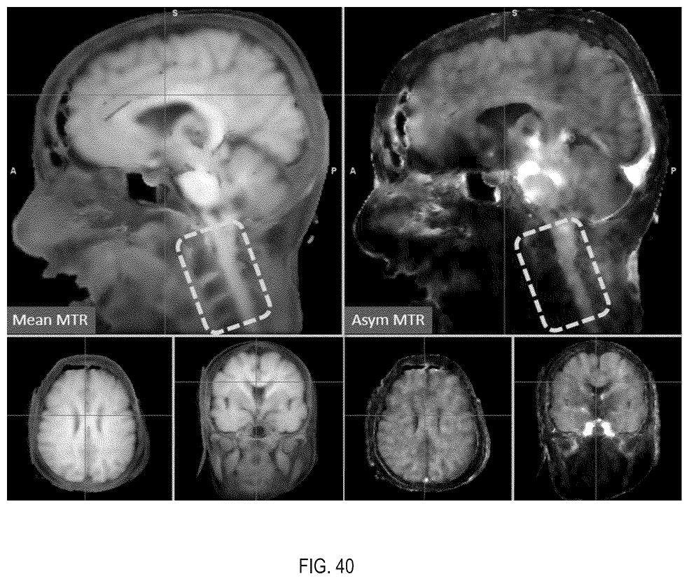

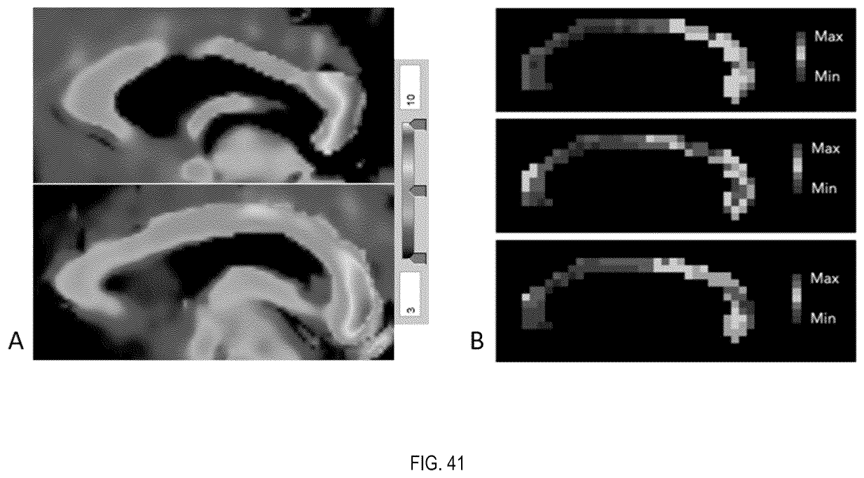

In some implementations, the images of different magnetization saturation conditions are shown in FIG. 38. The white matter signal was suppressed in saturation conditions at both +/−offset frequencies. It is also noticeable that the white matter was slightly more suppressed at the negative offset frequency than at the positive offset frequency. The three different MTR results are compared in FIG. 39. The MeanMTR has the best sensitivity and Asym2MTR shows an enhanced contrast when compared to Asym3MTR. The selectivity of myelin of the proposed Asym2MTR was demonstrated in FIG. 40 with the removal of spinal discs while leaving the spinal cords in comparison with the conventional MTR. The myelin content in the corpus callosum was distributed in the anterior-to-posterior direction with higher ratio at the posterior region as shown in FIG. 41, which is similar to the published histology results. The sensorimotor cortex contained high myelin content.

FIG. 38 shows transaxial slices of 3 different magnetization saturation conditions of (A) Off, (B) 4 KHz, and (C) −4 KHz. The image display window was kept the same. The white matter was suppressed progressively more from the off to the negative offset frequency.

FIG. 39 shows same transaxial slices as in FIG. 38 for 3 different MTR contrasts. The display window is noted in parentheses in the sub-figure title. The unit is percent.

FIG. 40 shows comparison of the conventional MTR (left pane) and the proposed Asym2MTR (right pane). The spine discs and cord are marked in a dotted yellow rectangle to demonstrate the filtering out of the spine discs in the asymmetric MTR.

FIG. 41 shows myelin mapping at the corpus callosum. Asym2MTR (left pane) and reported histology, showing the similar distribution of myelin content in the anterior-to-posterior direction with peaks at the posterior region.

Various embodiments in the present disclosure may offer faster, clearer, and more efficient imaging capabilities. Various embodiments offer at least one of the following improvements: reduced acquisition time, wherein by employing an ultra-short echo time, embodiments in the present disclosure significantly reduces the time required to capture images, minimizing the risk of distortion; enhanced image quality, wherein utilizing a three-dimensional excitation and acquisition approach results in superior signal-to-noise ratios, yielding clearer and more diagnostically valuable images; and/or efficient scanning, wherein the adoption of a non-Cartesian (or non-rectangular), spiral readout trajectory accelerates the scanning process, improving efficiency without compromising image quality.

The methods, devices, processing, and logic described above and below may be implemented in many different ways and in many different combinations of hardware and software. For example, all or parts of the implementations may be circuitry that includes an instruction processor, such as a Graphics Processing Unit (GPU), Central Processing Unit (CPU), microcontroller, or a microprocessor; an Application Specific Integrated Circuit (ASIC), Programmable Logic Device (PLD), or Field Programmable Gate Array (FPGA); or circuitry that includes discrete logic or other circuit components, including analog circuit components, digital circuit components or both; or any combination thereof. The circuitry may include discrete interconnected hardware components and/or may be combined on a single integrated circuit die, distributed among multiple integrated circuit dies, or implemented in a Multiple Chip Module (MCM) of multiple integrated circuit dies in a common package, as examples.

The circuitry may further include or access instructions for execution by the circuitry. The instructions may be embodied as a signal and/or data stream and/or may be stored in a tangible storage medium that is other than a transitory signal (i.e., non-transitory signal), such as a flash memory, a Random Access Memory (RAM), a Read Only Memory (ROM), an Erasable Programmable Read Only Memory (EPROM); or on a magnetic or optical disc, such as a Compact Disc Read Only Memory (CDROM), Hard Disk Drive (HDD), or other magnetic or optical disk; or in or on another machine-readable medium. A product, such as a computer program product, may particularly include a non-transitory storage medium and instructions stored in or on the medium, and the instructions when executed by the circuitry in a device may cause the device to implement any of the processing described above or illustrated in the drawings.

The implementations may be distributed as circuitry, e.g., hardware, and/or a combination of hardware and software among multiple system components, such as among multiple processors and memories, optionally including multiple distributed processing systems. Parameters, databases, and other data structures may be separately stored and managed, may be incorporated into a single memory or database, may be logically and physically organized in many different ways, and may be implemented in many different ways, including as data structures such as linked lists, hash tables, arrays, records, objects, or implicit storage mechanisms. Programs may be parts (e.g., subroutines) of a single program, separate programs, distributed across several memories and processors, or implemented in many different ways, such as in a library, such as a shared library (e.g., a Dynamic Link Library (DLL)). The DLL, for example, may store instructions that perform any of the processing described above or illustrated in the drawings, when executed by the circuitry.

In various embodiments in the present disclosure, a module may refer to a software module, a hardware module, or a combination thereof. A software module may include a computer program or part of the computer program that has a predefined function and works together with other related parts to achieve a predefined goal, such as those functions described in this disclosure. A hardware module may be implemented using processing circuitry and/or memory configured to perform the functions described in this disclosure. Each module can be implemented using one or more processors (or processors and memory). Likewise, a processor (or processors and memory) can be used to implement one or more modules. Moreover, each module can be part of an overall module that includes the functionalities of the module. The description here also applies to the term module and other equivalent terms.

While the particular disclosure has been described with reference to illustrative embodiments, this description is not meant to be limiting. Various modifications of the illustrative embodiments and additional embodiments of the disclosure will be apparent to one of ordinary skill in the art from this description. Those skilled in the art will readily recognize that these and various other modifications can be made to the exemplary embodiments, illustrated and described herein, without departing from the spirit and scope of the present disclosure. It is therefore contemplated that the appended claims will cover any such modifications and alternate embodiments. Certain proportions within the illustrations may be exaggerated, while other proportions may be minimized. Accordingly, the disclosure and the figures are to be regarded as illustrative rather than restrictive.

What is claimed is:

1. A method for performing magnetic resonance imaging (MRI) by a device comprising a memory storing instructions and a processor in communication with the memory, the method comprising:
for each of a plurality of data acquisition sequences:
applying a set of radio-frequency (RF) pulses to interact with transverse magnetization within an imaging volume of an object in a magnetic field,
applying a three-dimension (3D) magnetic gradient within the imaging volume, wherein the 3D magnetic gradient comprises a 3D spiral pulse, and
acquiring, during the 3D spiral pulse, raw imaging data from the imaging volume; and
constructing a raw MRI image based on the raw imaging data acquired from the plurality of data acquisition sequences.

2. The method according to claim 1, wherein:
the 3D magnetic gradient comprises a diffusion encoding gradient corresponding to a set of diffusion encoding factors; and
the diffusion encoding gradient comprises a diffusion-weighted (DW) steady-state free procession (SSFP) gradient.

3. The method according to claim 2, further comprising:
normalizing the raw MRI image to obtain a normalized MRI image according to the set of diffusion encoding factors.

4. The method according to claim 2, wherein:
the set of diffusion encoding factors correspond to a set of diffusion encoding directions and are obtained based on reference signal of a reference sample at the set of diffusion encoding directions; and
the reference sample has an isotropic diffusion property, and is a region-of-interest (ROI) within the object or a sample outside the object.

5. The method according to claim 4, wherein the acquiring, during the 3D spiral pulse, the raw imaging data from the imaging volume comprises:
acquiring, during the 3D spiral pulse, echo signal corresponding to the RF pulse from the imaging volume; and
processing the echo signal to obtain the raw imaging data.

6. The method according to claim 2, wherein:
the 3D spiral pulse comprises a time-variant magnetic gradient along at least one axis to form a spiral-in trajectory in a two-dimension (2D) disc in a 3D k-space; and
the time-variant magnetic gradient along at least one axis in the 3D changes from one data acquisition sequence to next data acquisition sequence to rotate the 2D disc to fill the 3D k-space.

7. The method according to claim 2, wherein:
the set of RF pulses comprises an excitation RF pulse; and
the excitation RF pulse is on-resonance to excite the transverse magnetization within the imaging volume.

8. The method according to claim 7, wherein:
the excitation RF pulse corresponds to a 30-degree flip angle,
the excitation RF pulse comprises a rectangular RF pulse, and
the magnetic field is about 7 Tesla.

9. The method according to claim 1, wherein:
the set of RF pulses comprises at least one pair of saturation pulses and one or more excitation RF pulses;
each saturation pulse pair comprises a first saturation pulse followed by a second saturation pulse, both of which are off-resonance to saturate the transverse magnetization within the imaging volume; and
the one or more excitation RF pulse is on-resonance to excite the transverse magnetization within the imaging volume.

10. The method according to claim 9, wherein:
each saturation pulse pair has at least one of the following configurations:
a PP configuration wherein the first saturation pulse and the second saturation pulse have an off-resonance frequency with a positive offset and the off-resonance frequency with the positive offset, respectively;
a NN configuration wherein the first saturation pulse and the second saturation pulse have an off-resonance frequency with a negative offset and the off-resonance frequency with the negative offset, respectively;
a PN configuration wherein the first saturation pulse and the second saturation pulse have the off-resonance frequency with the positive offset and the off-resonance frequency with the negative offset, respectively; or
a NP configuration wherein the first saturation pulse and the second saturation pulse have the off-resonance frequency with the negative offset and the off-resonance frequency with the positive offset, respectively.

11. The method according to claim 10, further comprising:
obtaining a MRI image based on a plurality of the raw MRI images according to at least one of the following:
$$[ {MT}_{PP} - [ ( M {T}_{PN} + M {T}_{NP} ) / 2 ] / {MT}_{off} \times 100 , or$$
$$[ {MT}_{PP} - [ ( M {T}_{NN} + M {T}_{PN} + M {T}_{NP} ) / 3 ] / {MT}_{off} \times 100 ,$$
wherein: MT_{PP} is magnetization transfer signal when the saturation pulse pair has the PP configuration, MT_{NN} is magnetization transfer signal when the saturation pulse pair has the NN configuration, MT_{PN} is magnetization transfer signal when the saturation pulse pair has the PN configuration, MT_{NP} is magnetization transfer signal when the saturation pulse pair has the NP configuration, MT_{OFF} is magnetization transfer signal when the saturation pulse pair is absent.

12. The method according to claim 9, wherein:
the 3D spiral pulse comprises a time-variant magnetic gradient along more than one axes to form a spiral-out trajectory in a two-dimension (2D) disc in a 3D k-space, and
the time-variant magnetic gradient in the 3D changes from one data acquisition sequence to next data acquisition sequence to rotate the 2D disc to fill the 3D k-space.

13. The method according to claim 12, wherein:
the 3D magnetic gradient comprises a saturation spoiler gradient after each saturation pulse pair along all three axes, and a readout spoiler gradient along the axis that does not have the time-variant magnetic gradient.

14. The method according to claim 1, wherein:
the set of RF pulses comprises a plurality of saturation pulses and one or more excitation RF pulses;
the plurality of saturation pulses are off-resonance to saturate the transverse magnetization within the imaging volume; and
the one or more excitation RF pulse is on-resonance to excite the transverse magnetization within the imaging volume.

15. The method according to claim 14, wherein:
the plurality of saturation pulses have at least one of the following configurations:
a P configuration wherein the plurality of saturation pulses have an off-resonance frequency with a positive offset; or
a N configuration wherein the plurality of saturation pulses have an off-resonance frequency with a negative offset.

16. The method according to claim 15, further comprising:
obtaining a MRI image based on a plurality of the raw MRI images according to at least one of the following:
$$[ ( {M}_{P} - {M}_{N} ) / ( {M}_{P} + {M}_{N} ) ] / 2 * 100 ,$$
$$[ ( {M}_{P} - {M}_{N} ) / {M}_{OFF} ] * 100 , or$$
$$[ {M}_{OFF} - [ ( {M}_{P} + {M}_{N} ) / 2 ] / {M}_{OFF} * 100 ,$$
wherein: MT_{P} is magnetization transfer signal when the plurality of saturation pulses have the P configuration, MT_{N} is magnetization transfer signal when the plurality of saturation pulses have the N configuration, and MT_{OFF} is magnetization transfer signal when the plurality of saturation pulses are absent.

17. The method according to claim 14, wherein:
the 3D spiral pulse comprises a time-variant magnetic gradient along more than one axes to form a spiral-out trajectory in a two-dimension (2D) disc in a 3D k-space,
the time-variant magnetic gradient in the 3D changes from one data acquisition sequence to next data acquisition sequence to rotate the 2D disc to fill the 3D k-space, and
the 3D magnetic gradient comprises a saturation spoiler gradient after each saturation pulse along all three axes, and a readout spoiler gradient along the axis that does not have the time-variant magnetic gradient.

18. The method according to claim 14, wherein:
each saturation pulse corresponds to a 160-degree flip angle,
the excitation RF pulse corresponds to a 5-degree flip angle, and
the magnetic field is about 7 Tesla.

19. An apparatus, comprising:
a memory storing instructions; and
a processor in communication with the memory, wherein, when the processor executes the instructions, the processor is configured to cause the apparatus to perform:
for each of a plurality of data acquisition sequences:
applying a set of radio-frequency (RF) pulses to interact with transverse magnetization within an imaging volume of an object in a magnetic field,
applying a three-dimension (3D) magnetic gradient within the imaging volume, wherein the 3D magnetic gradient comprises a 3D spiral pulse, and
acquiring, during the 3D spiral pulse, raw imaging data from the imaging volume; and
constructing a raw MRI image based on the raw imaging data acquired from the plurality of data acquisition sequences.

20. A non-transitory computer-readable medium storing computer-readable instructions, wherein, the computer-readable instructions, when executed by a processor, are configured to cause the processor to perform:
for each of a plurality of data acquisition sequences:
applying a set of radio-frequency (RF) pulses to interact with transverse magnetization within an imaging volume of an object in a magnetic field,
applying a three-dimension (3D) magnetic gradient within the imaging volume, wherein the 3D magnetic gradient comprises a 3D spiral pulse, and
acquiring, during the 3D spiral pulse, raw imaging data from the imaging volume; and
constructing a raw MRI image based on the raw imaging data acquired from the plurality of data acquisition sequences.
